(19) United States
(12) Patent Application Publication
(10) Pub. No.: US 2013/0083960 A1
(43) Pub. Date: Apr. 4, 2013

(54) FUNCTION-CENTRIC DATA SYSTEM

(71) Applicants: Andrew Kostrzewski, Garden Grove, CA (US); Sookwang Ro, Glendale, CA (US); Kang Lee, Woodland Hills, CA (US); Thomas Forrester, Hacienda Heights, CA (US); Tomasz Jannzon, Torrance, CA (US)

(72) Inventors: Andrew Kostrzewski, Garden Grove, CA (US); Sookwang Ro, Glendale, CA (US); Kang Lee, Woodland Hills, CA (US); Thomas Forrester, Hacienda Heights, CA (US); Tomasz Jannzon, Torrance, CA (US)

(21) Appl. No.: 13/304,515

(22) Filed: Nov. 25, 2011

Related U.S. Application Data
(60) Provisional application No. 61/558,979, filed on Nov. 11, 2011.
(60) Provisional application No. 61/541,885, filed on Sep. 30, 2011.
(60) Provisional application No. 61/547,612, filed on Oct. 14, 2011.

(51) Int. Cl. G06F 15/00; H04W 36/00; G06K 9/62; H05K 5/02; H05K 7/00

(52) U.S. Cl. 382/103; 361/679.01; 361/679.31; 702/35; 370/331

(57) ABSTRACT

Various embodiments of the invention provide a function centric data system that reduces avionics system weight and power requirements. In some embodiments, the function centric data system is housed in a vibration resistant package. A variety of functions typically performed by other avionics systems are incorporated into the system, allowing centralize power and processing management, reducing weight and improving system reliability. In some embodiments, the function centric data system is configured to provide high rate data sampling, allowing ground stations to apply sophisticated failure prediction algorithms, reducing maintenance costs and mean time between flights. Embodiments include methods of wireless networking with automatic hand offs and adaptive multi-hop topologies to allow this data to be promptly transferred when the aircraft lands. Embodiments also include methods for data processing to predict imminent failures using Bayesian statistics and catastrophe prediction methods.

### CROSS-REFERENCE TO RELATED APPLICATIONS

This application claims the benefit of U.S. Provisional Application No. 61/558,979, filed Nov. 11, 2011; U.S. Provisional Application No. 61/541,885, filed Sep. 30, 2011; and U.S. Provisional Application No. 61/547,612, filed Oct. 14, 2011, which are hereby incorporated herein by reference in their entireties.

### STATEMENT OF RIGHTS TO INVENTIONS MADE UNDER FEDERALLY SPONSORED RESEARCH

This invention was made with Government support under Navy-W-LINK II Contract No. N68335-06-C-0357 and Contract No. N68335-08-C-0080 awarded by the Navy. The Government has certain rights in the invention.

### TECHNICAL FIELD

The present invention relates generally to avionics systems, and more particularly, some embodiments relate to data acquisition units in avionics systems.

### DESCRIPTION OF THE RELATED ART

Many modern avionics systems, particularly in defense applications, include a broad range of loosely coupled electronic assemblies (such as weapons replaceable assemblies (WRAs)) communicating over slow bus lines such as a MIL SDT 1553 bus. Such assemblies include avionic data recorders (ADRs), mission computers (MCs), terrain awareness warning systems (TAWS), video recorders (VRs), mission data loaders (MDLs), audio recorders (ARs), crash protected memory (CPM), sensor acquisition units (SAUs), RISC processors, analog sensor recorders, and signal data or advanced signal data computers. Each of these systems requires some processing power and electrical power, increasing weight and costing power. Their distribution throughout the aircraft

Many of these systems collect data, collect data from sensors, or generate report data during operation (for example, during flight). This data is then provided to on ground operators to review. After flight, the data is reviewed before the aircraft is cleared for flight again. Data throughput, power, and space considerations limit the data provided to the ground operators to brief snapshots, limited to a few Hz, and counts of when specific systems exceeded predetermined thresholds (termed, “exceedences”). Review of this limited data results in over-reporting of possible problems, resulting in over maintenance, increased expense, and increased mean time between flights.

Existing avionics systems, particularly command and control or monitoring systems, are configured manually by flight line technicians and engineers. In civilian aircraft, especially large passenger planes have engines, sensors, and other electronic and electromechanical subsystems that are configured only once or at the most, infrequently, often with years or even decades passing in between configuration cycles. This is because their subsystems rarely, if ever, change configuration after the aircraft is placed in service. In contrast to this, military aircraft, such as fighter planes, helicopters, and reconnaissance aircraft are often reconfigured dynamically—sometimes with each sortie.

Existing avionics monitoring and control systems are simply not designed to automatically, let alone autonomously, dynamically reconfigure themselves when the aircraft environment changes—such as when weapons are added/removed, sensors are changed, and special payloads are flown. For instance, the same surveillance aircraft may be flown during the day with visual-band cameras/sensors and at night with infrared cameras/sensors. Or, a fighter plane may fly with missiles on one sortie and on another sortie without them. A bomber aircraft may be reconfigured with differently-deployed weapons.

Additionally, when a command and control or monitoring unit fails and requires replacement, a time- and labor-intensive manual configuration process must take place which limits the amount of time that the aircraft can be in the air. This can severely impact military flight operations and limits force effectiveness.

### BRIEF SUMMARY OF EMBODIMENTS OF THE INVENTION

Various embodiments of the invention provide a function centric data system that reduces avionics system weight and power requirements. In some embodiments, the function centric data system is housed in a vibration resistant package. A variety of functions typically performed by other avionics systems are incorporated into the system, allowing centralize power and processing management, reducing weight and improving system reliability. In some embodiments, the function centric data system is configured to provide high rate data sampling, allowing ground stations to apply sophisticated failure prediction algorithms, reducing maintenance costs and mean time between flights. Embodiments include methods of wireless networking with automatic hand offs and adaptive multi-hop topologies to allow this data to be promptly transferred when the aircraft lands. Embodiments also include methods for data processing to predict imminent failures using Bayesian statistics and catastrophe prediction methods.

Other features and aspects of the invention will become apparent from the following detailed description, taken in conjunction with the accompanying drawings, which illustrate, by way of example, the features in accordance with embodiments of the invention. The summary is not intended to limit the scope of the invention, which is defined solely by the claims attached hereto.

Additionally, although modules, functions, and systems are described herein with respect to aircraft and avionics systems, many embodiments of the invention are applicable in ground vehicles and unattended ground platforms, in addition to airborne platforms.

### BRIEF DESCRIPTION OF THE DRAWINGS

The present invention, in accordance with one or more various embodiments, is described in detail with reference to the following figures. The drawings are provided for purposes of illustration only and merely depict typical or example embodiments of the invention. These drawings are provided to facilitate the reader's understanding of the invention and shall not be considered limiting of the breadth, scope, or applicability of the invention. It should be noted that for clarity and ease of illustration these drawings are not necessarily made to scale.

FIG. 1 illustrates a heatsink and radiating device connected to a heat source.

FIG. 2A illustrates vibrational isolation and amplification conditions for objects subject to driving oscillations.

FIGS. 2B-2I illustrates a plurality of pseudo-fractal electronics housings implemented in accordance with an embodiment of the invention.

FIG. 2J illustrates a distributed resonant frequency structure in the frequency domain of a pseudo-fractal electronics housing implemented in accordance with an embodiment of the invention.

FIGS. 3A and 3B illustrates a function centric data system implemented in accordance with an embodiment of the invention.

FIG. 4 illustrates a second function centric data system implemented in accordance with an embodiment of the invention.

FIG. 5 illustrates an operational flight program implemented in accordance with an embodiment of the invention.

FIG. 6 illustrates a method of self-reconfiguration implemented in accordance with an embodiment of the invention.

FIGS. 7A and 7B illustrate a method of data sampling implemented in accordance with an embodiment of the invention.

FIGS. 8A-8D illustrate networking systems implemented in accordance with embodiments of the invention.

FIG. 9 illustrates a network centric view of a function centric data system implemented in accordance with an embodiment of the invention.

FIGS. 10A-10F illustrate methods of data digitization implemented in accordance with an embodiment of the invention.

FIGS. 11A-J illustrate methods of data processing for predicting system failures implemented in accordance with an embodiment of the invention.

FIG. 12 illustrates an example computing module that may be used in implementing various features of embodiments of the invention.

The figures are not intended to be exhaustive or to limit the invention to the precise form disclosed. It should be understood that the invention can be practiced with modification and alteration, and that the invention be limited only by the claims and the equivalents thereof.

### DETAILED DESCRIPTION OF THE EMBODIMENTS OF THE INVENTION

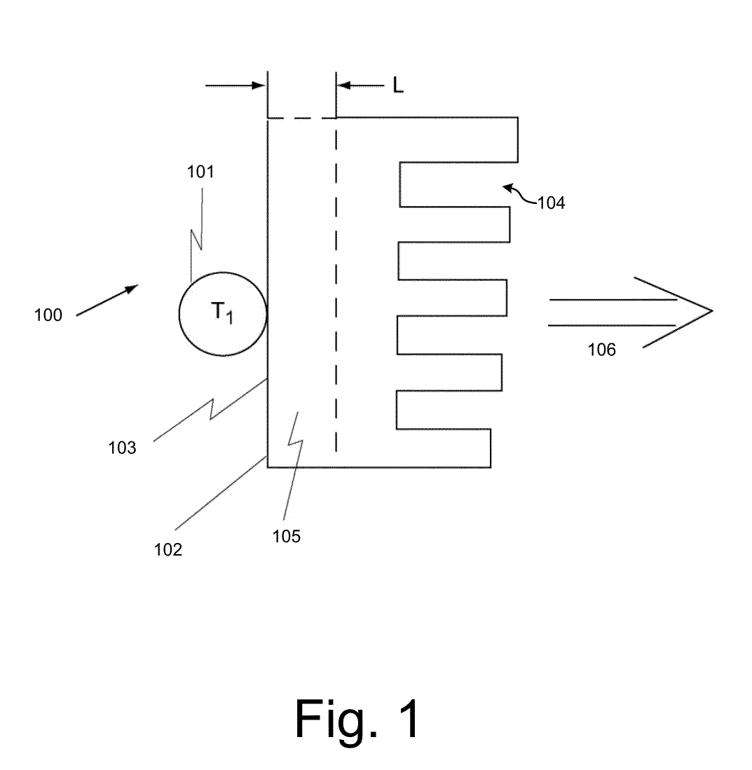

Some embodiments of the invention comprise electronics housing that are resistant to damage caused by mechanical vibration and assist in heat transfer to outside the housings. FIG. 1 illustrates general heat transport considerations. Generally, a thermal interface 100 has a thermal time constant, τ, of the global heat transfer from 100 to 106, in the form:

Σ=RC (1-1)

where R is global resistance and C is global capacitance, using the lamped impedance method for transient heat transport which includes, in general, all types of heat, by: conduction, convection and radiation. In order to transmit heat into an external region 106, it is desirable to achieve a low thermal time constant.

In transient conditions, the thermal source temperature, T₁, 101 has, initially, temperature Tₒ (i.e., at t=0, T₁=Tₒ). For example, the thermal source might be an electrical circuit, IC. After infinite time, t=∞, the circuit 101 will reach the same temperature as the external region 106, i.e., temperature T_{∞}. For finite time, t, its 101 temperature T₁, will be lower than Tₒ, but higher than T_{∞}, satisfying the following approximate general relation:

T_{∞}−T₁=(T_{∞}−Tₒ)e^{-t/τ} (1-2)

Accordingly, to achieve fast heat transport, the τ-time constant should be low. As illustrated, the heat source 101 is in thermal contact with a thermally conductive material 102. Accordingly, fast heat transport is achieved with lower time constants through the conductive material 102—in particular, at a thin surface region 103 of the material 102. In particular embodiments, the thermally conductive material 102 is the chassis for the electronics heat source 101. In this embodiment, the chassis 102 may further include a wall or panel 105 with thickness L. Here, the surface 103 in contact with heat source 101 is the inner surface of panel 105. To facilitate heat transfer, the panel 105 should also have as small time constant as possible. (For clarity, this discussion assumes transient heat transfer conditions. The extension to steady-state conditions is straight forward: in order to deal with high temperature gradients high Blot numbers are applied.)

In some embodiments, the chassis 105 is coupled to a radiator 104 to further maximize heat transport. The general idea of heat radiator is to maximize its surface, A. However, this surface maximization cannot be done at the expense of compromising with mean free path value, l, value of the convection medium surrounding the radiator 104. In elementary theory, the medium layer with infinitesimal thickness, dx, is filled with particles, where n is the number of them per unit volume, while σ is the effective cross-section for collision between them.

Theses collisions cause a drop in the beam intensity of the stream of such particles, I. Its relative drop will be proportional to dx, n and σ, in the form:

$$- \frac{d I}{I} = - n σ dx \qquad ( 1 \text{-} 3 )$$

After integrating this equation, we obtain: ln I=−nσx+ln Iₒ, Iₒ=I(o), and ln( . . . ) is the natural logarithmic operation. From this, we obtain

I=Iₒe^{-nσx}=Iₒe^{-x/l}; l=(nσ)⁻¹ (1-4)

where l is the mean free path, according to this elementary theory. As appreciated in the art, under the more precise Maxwell kinetic theory, we obtain the more exact formula:

l=(\sqrt{2}nσ)⁻¹ (1-5)

For example, for air in normal pressure of 1 At and typical n=2.7·10¹⁴ cm⁻³, we obtain l≈70 nm; i.e., very small value, but for higher pressures, higher density gases, or fluids, —as in the case of forced air or liquid cooling—this number will be higher. As discussed below, in some embodiments, surface cavities are introduced into the chassis 102 of electrical packaging. In embodiments where thermal management is a limiting factor, the surface cavities, (for example, in radiator 104), are not comparable, or smaller than l, since, in such a case, the heat convection will be significantly reduced.

In the general theory of vibrations, all bodies have characteristic frequencies of vibrations, fₙ, or angular frequencies, ωₙ, where ωₙ=2πfₙ, and fₙ is so-called natural frequency, or resonance frequency. In the elementary (lumped) case, ωₙ=\sqrt{k/m}, where m is mass of a given body, while k is the vibration constant, which is a proportionality coefficient of stimulated harmonic vibration force, F, with frequency, ω_{b}; i.e., F=−kx, where x is a deflection coordinate, with amplitude A; i.e., |x|≦A. Then, in order to damp such vibration, for example, in viscous damping, with damping constant, ξ, when, for ξ=1, we have so-called critically-damped motion, while for ξ_{>}²¹ 1, we have underdamped, or overdamped cases, respectively. The damping effect is directly related to energy loss, ΔE, characterized by so-called loss function, η, while ΔE is also characterizing hysteresis area, and η=2ξ. Typical η-values for nitride rubber, for example, are within 0.2-1.0 range, depending on temperature T° (F.) and frequency, f, in Hz. For example, for T=75° and f=10 Hz, we have η=0.21, while for T=50° and f=100 Hz, η=0.5 and Young module, E′, is: 4.14·10⁷ N/m². Other materials have n-values as follows: Al—0.006, steel—0.07, neoprene—0.1, butyl rubber—0.4, and thermoplastic—1.0.

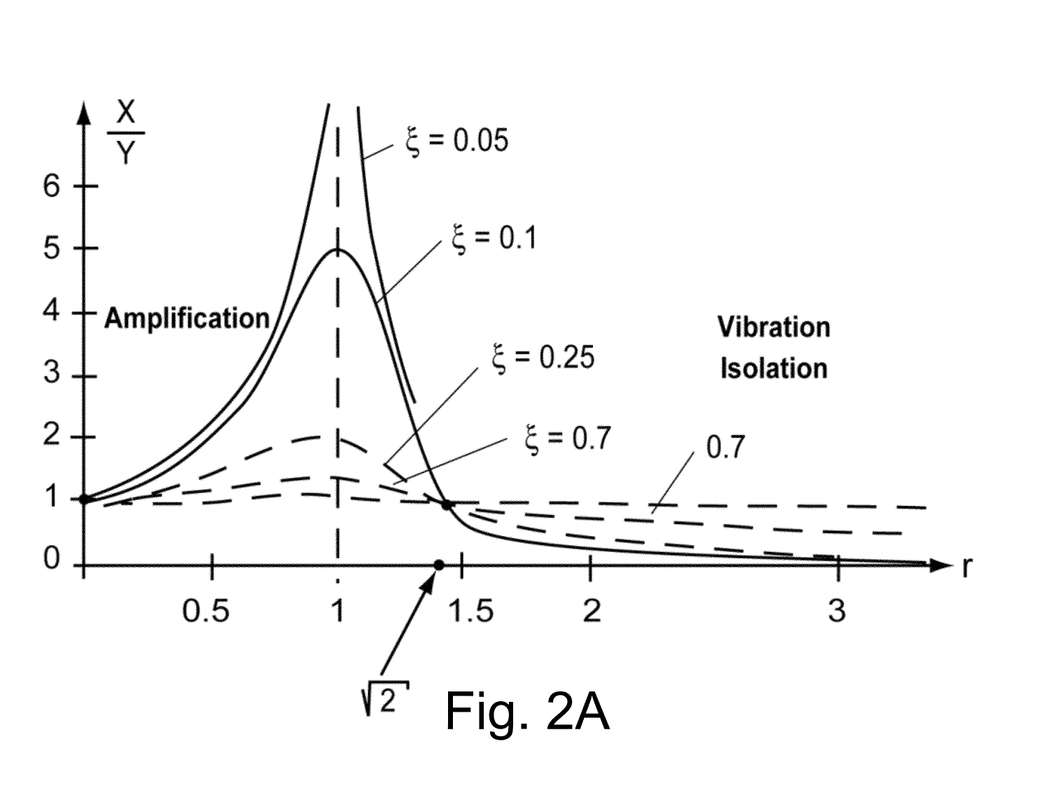

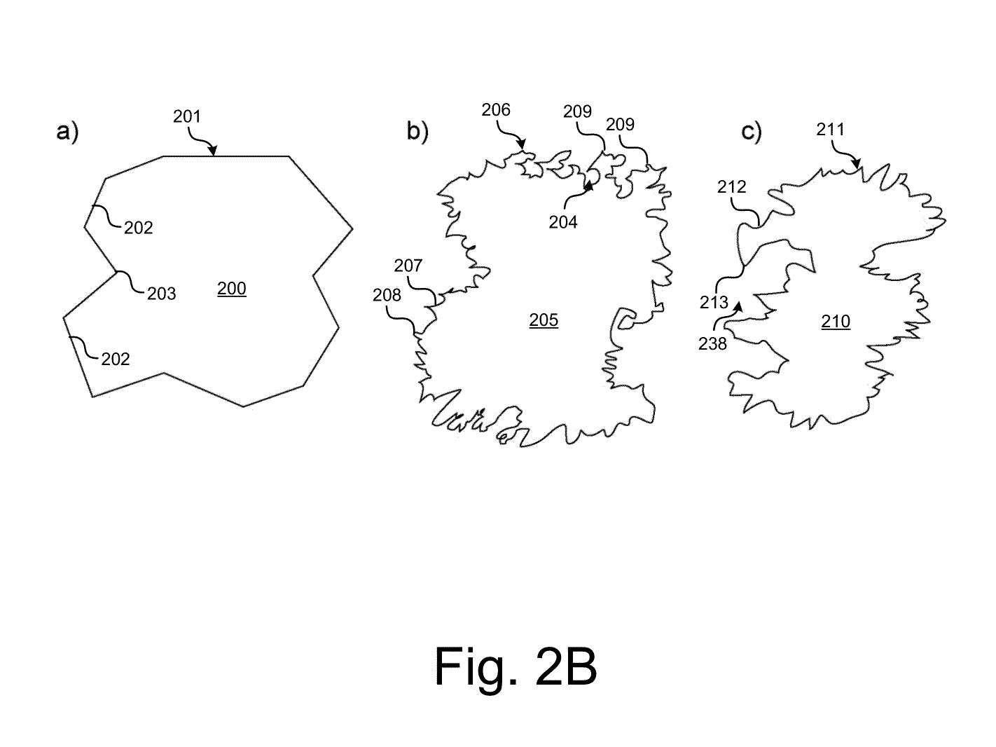

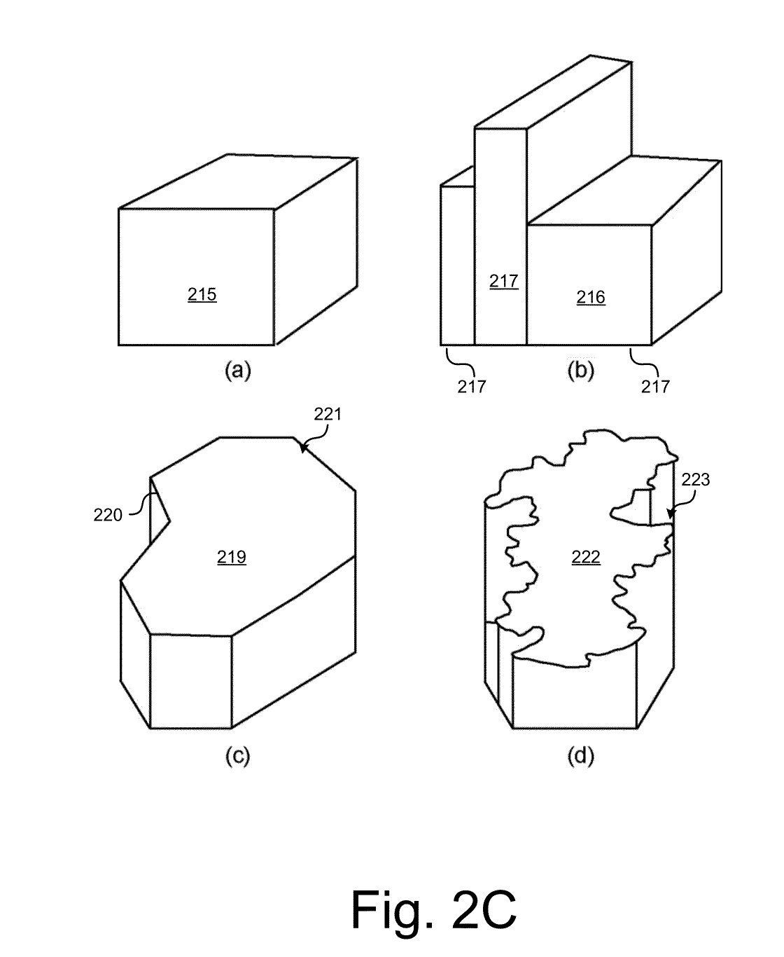

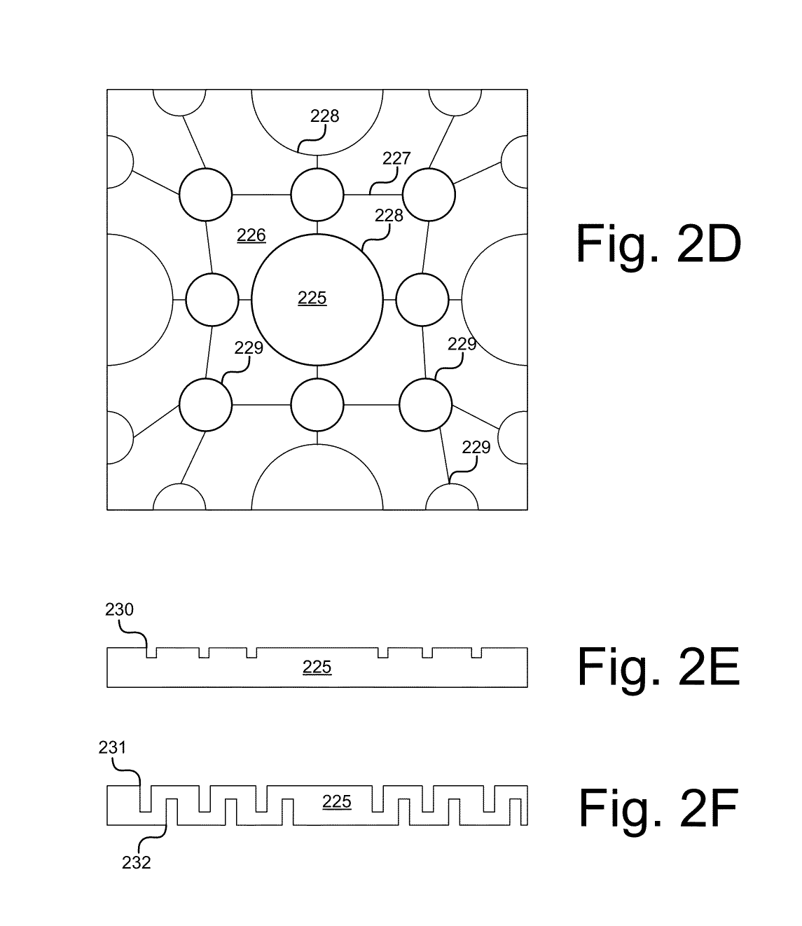

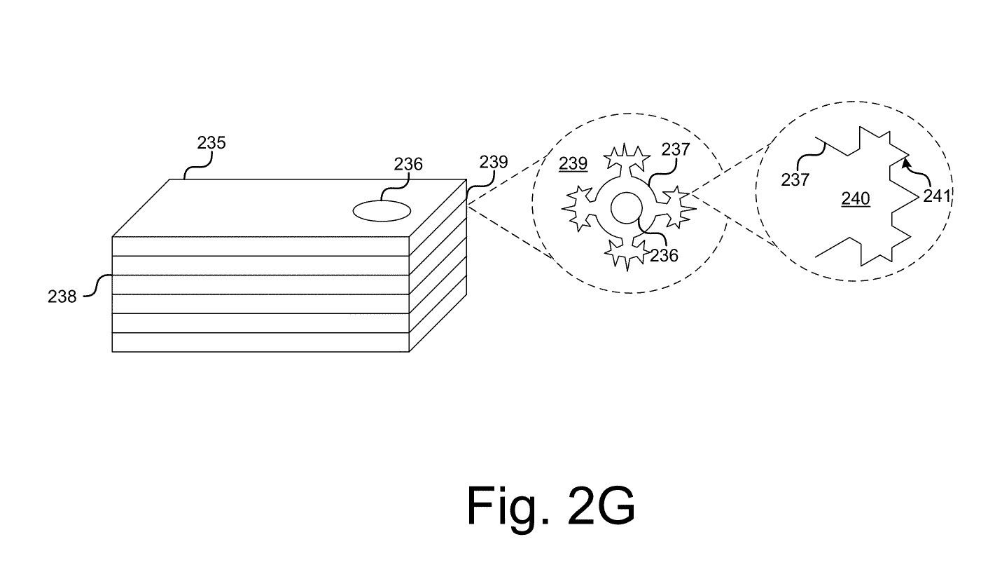

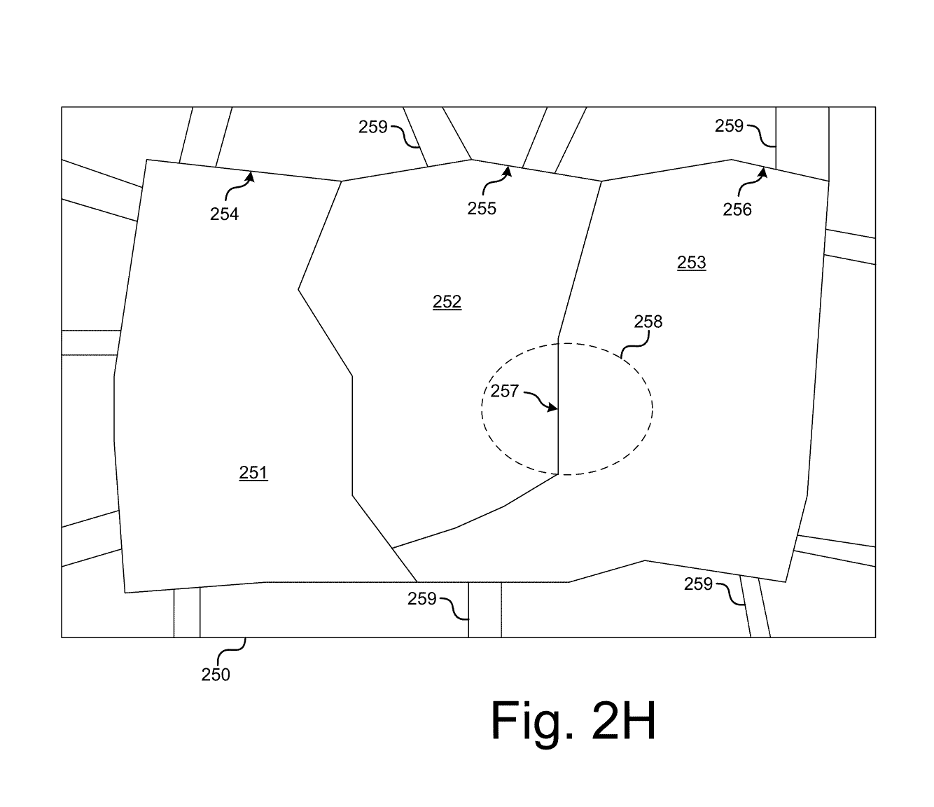

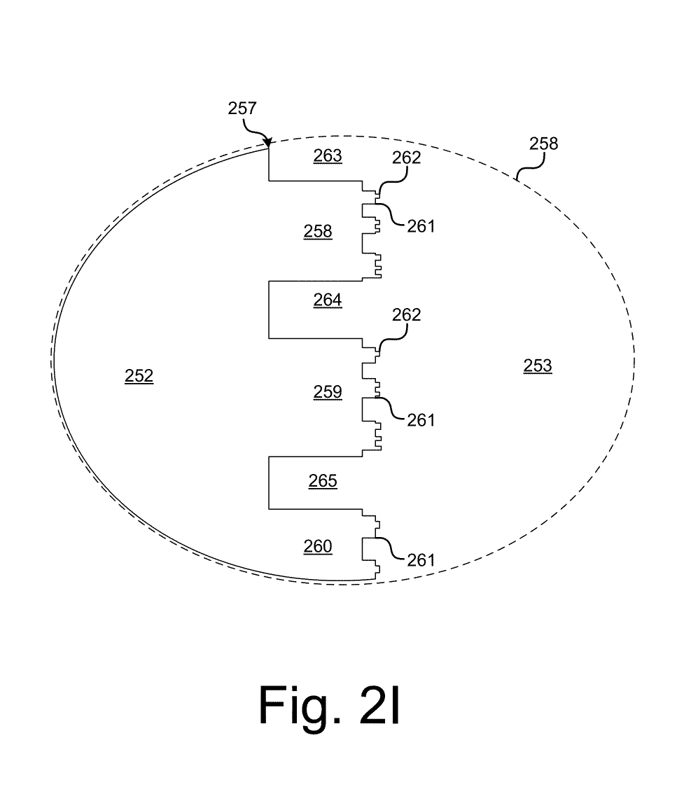

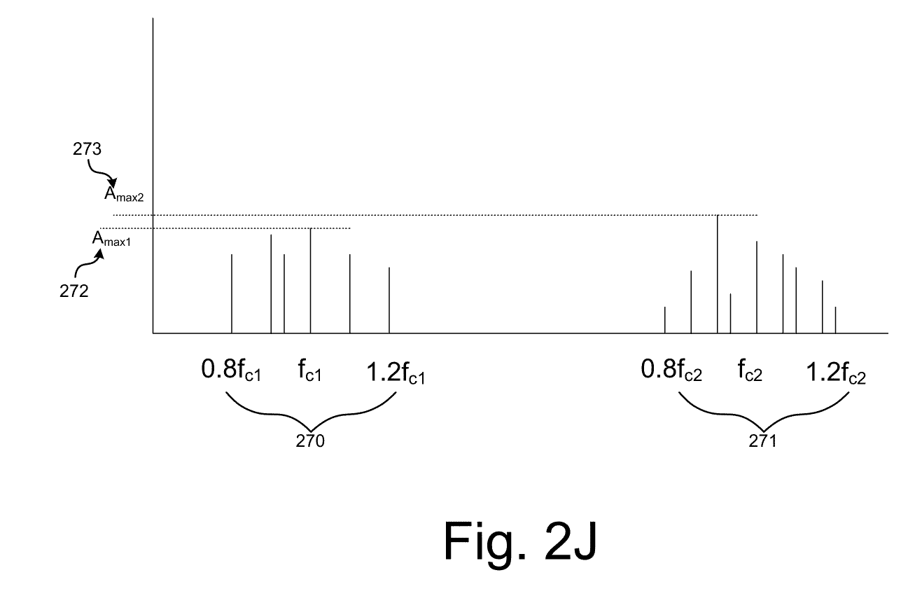

In the elementary case, when a body is stimulated with amplitude Y and angular frequency ω_{b}, while body's natural frequency is ωₙ, and its amplitude of vibration, X, in order to avoid catastrophic amplification of vibrations, with infinite value of (X/Y), we need to introduce a damping with damping constant, ξ. Typically, we introduce frequency ratio coefficient, in the form: r=ω_{b}/ωₙ. Then, typical dependence of ratio: (X/Y) as function of r-value, has the form as in FIG. 2A. We see that for r>\sqrt{2}, we have X/Y≦1 which is called vibration isolation. Otherwise, we have X/Y≧1; i.e., vibration amplification. However, due to damping (ξ<∞), we avoid catastrophic amplification: X/Y=∞. A higher ξ-value causes a lower peak of vibrations at resonant frequency at: r=1. For example, for ξ=0.1, we have: X/Y=5. However, for ξ=0.25, we have: X/Y=2. In general, we see that for high stimulated frequencies, when:

r>>\sqrt{2} (1-6)

we have

$$\frac{X}{Y} < 1. \qquad ( 1 \text{-} 7 )$$

Accordingly, if ωₙ increases then the ω_{b}-values must be respectively higher, in order to obtain vibration isolation.

In order to more accurately treat real world application, the more advanced case of distributed constants is applied instead of lumped constants as above. Here, the idea of vibrations as a function of time, only, is generalized to wave propagation, where instead of 2D-space (x,t), we need to discuss 4D-space (x,y,z,t). Accordingly, in solid bodies (solids) case (metal, plastic, etc.), longitudinal waves, with speed, Vₗ, propagating mostly in volume (including, also, fluids and gases, such as air) and transversal (elastic) waves, propagating mostly on surface with speed Vₜ, (which can be function of direction, especially for crystals) are both analyzed. Attenuation of sound in solids, which can be measured in dB, or in Nepers, in m⁻¹, is also analyzed. For example, for aluminum, the attenuation is 0.4 m⁻¹, coming from the fact that attenuation coefficient, β, is in m⁻¹, where amplitude of sound is attenuated as: e^{-βx}, where x is in meters. Then, exp(−0.4)=0.67, and: −10 log 0.67=1.737 dB/m=1.737 dB/km. Table 1 presents sound speeds and attenuation in some solids.

TABLE 1
Speed of Sound and Attenuation in Solids: Vₑ—Longitudinal,
Vₜ—Transversal

| Solid | Vᵢ | Vₜ | Neper m⁻¹ |
|---|---|---|---|
| Aluminum | 6,374 ms⁻¹ | 3111 ms⁻¹ | 0.4 |
| Human Bone | 4,000 | 1,970 | 460 |
| Copper | 4,759 | 2,335 | — |
| Glass | 5,660 | 3,620 | 2 |
| Nylon | 2,680 | — | 13 |
| Polycarbonate | 2,220 | 910 | 240 |
| Silver | 3,740 | 1,698 | — |
| Steel | 5,874 | 3,179 | 4.94 |
| Zinc | 4,187 | 2,421 | — |
| Rubber | 1,600 | — | 15 |

Dependence of sound attenuation as a function of frequency in solids is complicated. This is because the attenuation of sound in solids is connected with their viscosity and heat dissipation. In the case of isotropic and amorphous bodies, the attenuation coefficient, βₜ, for transversal waves, is

βₜ=γω²/2ρVₜ³ (1-8)

i.e., proportional to frequency square: ω², where γ is dynamic viscosity coefficient in kgm⁻¹s⁻¹, ρ-material density and Vₜ-speed. The analogous formula for βₑ is much more complex but it has also proportionality to ω² and inverse proportionality to Vₗ³. For polycrystalline bodies the situation is more complex and β-function depends on how size of crystallines, a, is in comparison to wave wavelength, λ. In some cases β is proportional to \sqrt{ω}, and proportional to speed of waves.

In the case of sound propagation in human bodies, the situation is well analyzed for ultrasound (f>100 kHz), and β-coefficient is proportional to f, presented in dB/MHz·cm=α, where for blood α=0.2 dB/MHz·cm, and for other body parts: bone—6.9, brain—0.6, breast—0.75, cardiac—0.52, connective tissue—1.57, dentin—80, fat—120, liver—0.5, muscle—1.09, soft tissue—0.54 and water—0.0022.

The attenuation of sound in air as a function of frequency, in kHz, is: for 1 kHz and 10%-relative humidity: β=14 dBkm⁻¹. Also, for 10%-relative humidity and various frequencies in kHz, we have: 1.25-2, 16-32, 2-45, 2.5-63, 4-110, 5-130, 6.3-160, 8-180, 10*-190, 16-230, 20-260, 25-300, 31.5-360, 40-460, 50-600, 63-860, 80-1200, and 100-1800. As this illustrates, attenuation strongly increases as a function of sound frequency. Similarly, in fluids, the β-coefficient is usually proportional to ω².

For typical amorphous building materials the absorption coefficients in % as a total, for such materials as carpet, vinyl, wood, drapery, fiberglass, cellulose fiber, water, are such that: for f=125 Hz, we have very low absorption (^{˜}1%), for f=250 Hz, still low (2-3%), for 500 Hz up to 10%, for 1 kHz about 20%. The specific absorption values in % for f=4 kHz, are: carpet—45%, vinyl—2%, wood=50%, drapery—35%, glass—2%, fiberglass—99%, cellulose fiber—100%, water—2%. We see that material structure is essential feature, as seen in fiberglass and cellulose fiber, where fiber-structure provides full absorption of sound.

The above properties of sound absorption in solids, liquids and air have been given as examples. As FIG. 2 illustrates, high resonant frequency, ωₙ, values should be avoided. Therefore, high values of vibration amplitude, A, are avoided in order to minimize resonant frequency harmonies:

mωₙ, m=2, 3, 4, (1-9)

Also, from theory of elastic plates, say, square plates, with sizes, a, embodiments avoid small wavelengths of standing waves, represented by such x,y-deflection distributions as (assuming nodes at boundaries):

$$sin \frac{m π x}{a} , m = 1 , 2 , 3 , 4 , … . \qquad ( 1 \text{-} 10 )$$

These mostly transversal surface waves, satisfying general relation: V=X·f, when V is specific speed of (mostly) transversal elastic wave, λ—its wavelength, and f—its frequency. For example, for nylon with V=1000 m/sec, and standing wave relation:

$$\frac{m λ}{2} = a \qquad ( 1 \text{-} 11 )$$

we have, for m=1: λ=2a, and for a=10 cm, λ=20 cm, we obtain:

$$f = \frac{V}{λ} = \frac{1000 m \text{/} sec}{20 cm} = 5 kHz . \qquad ( 1 \text{-} 12 )$$

Accordingly, in some embodiments, electronics systems are packaged in casings that avoid high resonant frequencies, fₙ, obtained either from harmonies, or from small plates. However, high frequencies are usually attenuated in solids through f²-proportionality, as in Eq. (11-8), and in the above selected data. FIG. 2B illustrates conceptual examples of such casings. Casing 200 is comprised of irregular surfaces 201, forming a pseudo fractal structure. These irregular surfaces are pseudo-fractal, meaning that large surfaces are broken up into smaller surfaces such that the resonant frequencies of the structure as a whole are a plurality of distributed frequency groups. FIG. 2J illustrates the resonant frequencies of an electronics housing with a pseudo-fractal structure. As illustrates, the pseudo fractal structure has one or more distributions, 270 and 271, of resonant frequencies. In some embodiments, the pseudo fractal structure may be configured so that the frequencies of the distribution(s) 210 and 271 are greater than a predetermined threshold frequencies, (i.e., they are in the vibration isolation region of FIG. 2A.) Additionally, the pseudo fractal structure may be configured so that the maximum amplitude 272 or 273 of the vibrations for a given distribution 270 or 271, respectively, is less than a predetermined threshold amplitude when the structure is exposed to a predetermined level of driving vibrations—for example, what would typically be present in an aircraft during operation.

The smaller surfaces are broken up into even smaller surfaces, and so on to a predetermined level. The pseudo-fractal surfaces 201 do not necessarily exhibit complete self similarity, although some may. The contours 202 of the surface may be sized differently from each other. Additionally, the points 203 where the contours 202 join may have varying angles. The pseudo-fractal surfaces Additionally, the pseudo-fractal surfaces may be quasi-fractal, meaning that the smallest size features in the contours 201 are larger than some predetermined threshold. The pseudo-fractal surfaces reduce the number of flat planes in the case, preventing the surfaces from having a single or a narrowly distributed range of high resonant frequencies. Rather, the high resonant frequencies are eliminated or distributed in a broad range. In some embodiments, the degree of quasi-fractalness may be predetermined according to a desired distribution of resonant frequencies.

FIG. 2B illustrates three different quasi-fractal casings 200, 205, and 210. In each casing, the level of pseudo self-similarity varies. For example, in casing 200, the quasi-fractal contour 201 is low level, with only a few straight contours 202 broken up at semi-regular intervals at points 203. At this level, some higher resonant frequencies are reduced or eliminated, but some still remain. The casing 205 has a higher level quasi-fractal contour 206. The casing is distributed into contours 209 and 207 joined together at points 208. As illustrated, the contours are pseudo-fractal and do not exhibit complete self-similarity. Accordingly, the surface features in this embodiment have reduced high level resonant frequencies, although the basic resonant frequency (and its harmonies), while highly-reduced, remains.

As illustrated, at a certain fractal level, portions of the casing 209 may create pockets 204, and as described above, these pockets may impede thermal radiation, creating problems with heat transfer. This occurs when cavities 204 are comparable or smaller than the mean-free-path, l, as in Eq. (1-5); in the following form:

a≦l. (1-13)

Casing 210 has a pseudo-fractal contour 211 that is a compromise between the low order contour 201 and high order contour 206. In this embodiment, the quasi-fractal order is high enough that the surface area is increased to a predetermined level, but low enough that cavities are larger than the mean-free-path of the surrounding material. In this embodiment, higher frequency resonances are not mitigated to the degree present in casing 205, however, the quasi-fractal structure reduces the higher frequencies and distributes resonant frequencies to below a predetermined level. In this embodiment, casing 210 provides a broad range of many high resonant frequencies, in a distributed form. Because the quasi-fractal features 213 and 212 leave cavities 214 larger than the mean-free-path of the surrounding material (for example, air), the surface area of the casing 210 increases the heat dissipation of the casing while reducing high resonant frequencies.

FIG. 2C illustrates various cases implemented in accordance with an embodiment of the invention. Case 215 illustrates a standard electrical housing, illustrated as a rectangular prism. Case 216 is broken up into a plurality of rectangular prism cases 217. This case represents a progression from standard cases 215, resulting in a distribution of higher order resonant frequencies. Case 219 illustrates a low order pseudo-fractal 220 prism. Case 222 illustrates a medium order pseudo fractal 223 prism. In this embodiment, the pseudo-fractal 223 has features that are on the order of or larger than the mean-free path of the environment to which the case will be exposed.

Although illustrated as a prism with flat faces, in some embodiments, the faces of the cases may also have pseudo-fractal features. Additionally, the figures are not to scale, and the depth of the pseudo-fractal features may be significantly less than illustrated. Cases implemented in accordance with these embodiments may be constructed of standard materials. However, in some embodiments, cases are constructed of fiber-based materials (such as fiber glass), configured to attenuate stimulating frequencies, ω_{b}, thereby avoiding high frequencies, ω_{b}, arriving at a given box location.

FIGS. 2D-2F illustrate a pseudo-fractal case implemented in accordance with an embodiment of the invention. In this embodiment, the pseudo-fractal case does not comprise bends or seams in the surface profile of the case. Rather, the pseudo-fractal features are etched 230, 231, or 232 into the surface of the case walls 225. In this particular embodiment, the case comprises a plurality of panels 225, etched with pseudo fractal features. The features of this embodiment comprise a series of curves 228, and 229. The circles are connected by a sequence of lines 227. The quasi-fractal order of the panel determines the smallest curve in the sequence 228, 229 . . . . Additional curves for higher quasi-fractal orders are disposed in the planes between lower order curves. For example, the illustrated pseudo-fractal has an order of two. A third order pseudo-fractal pattern would have a circle disposed in the plane region 226, with lines connecting the second and first order curves 229 and 228, respectively. Although illustrated as a collection of circles and lines, the pseudo-fractal patterns may vary in different embodiments. Any pseudo-fractal pattern that breaks the panel surface into smaller irregular plane regions 226 may be employed. These patterns reduce and distribute higher order resonate frequencies in the panel 225, reducing the likelihood of damage from driving vibrations.

FIGS. 2E and 2F are side view of panels 225 that illustrate prevention of higher order standing surface waves and internal waves. In the embodiment of FIG. 2E, the pattern is etched 230 in the surface of the panel 225, preventing or reducing the impact of standing surface waves. In the embodiment of FIG. 2F, the depth of the etches 231 is deeper, preventing vibrational waves inside the body of the panel 225 as well as surface waves. Additionally, patterns may be etched from both sides 231 and 232 of the panel. Additionally, the material removed from the etched patterns 230, 231, and 232 may be replaced with other materials filling the regions. For example, the etched patterns 230, 231, or 232 may be filled with fiberglass materials, epoxies, plastics, metals, or other structural materials.

FIG. 2G illustrates a pseudo-fractal feature embedded in an IC in accordance with an embodiment of the invention. Often integrated circuits (ICs) 235 are deposited on multilayered 238 substrates. For example, circuit boards 235 may comprise a plurality of laminate materials, such as FR-4. Circuit boards 235 frequently have through holes 236 for mounting the boards in cases or other packages. In some embodiments, one or more 239 of the interstitial layers 238 have pseudo fractal structures 237 surrounding the through hole 236. For example, the pseudo fractal pattern 237 may be a metal or other material embedded in a layer 239, or may be etched in the layer 239 as illustrated in FIGS. 2D-E. The presence of the pseudo-fractal structure 237 may prevent transmission of vibrations of fasteners disposed in the through-holes 236 to the circuit board. The illustrated pseudo-fractal pattern 237 is a generalized Koch Snowflake—other embodiments may employ other pseudo-fractal patterns. As illustrated, the pseudo-fractal structure 327 exhibits a predetermined amount of self-similarity 241. In this embodiment, as illustrated, there are five levels of general self-similarity 241. In further embodiments, one or more of the layers may have pseudo-fractal patterns covering the layer, as illustrated in FIGS. 2D-2F.

FIG. 2H illustrates a vibration reducing electronics housing implemented in accordance with an embodiment of the invention. In this embodiment, a system housing 250 is configured to be installed in an aircraft—for example, an avionics bay. The housing 250 houses a plurality of electronics modules 251, 252, and 253. For example, the modules may be any of a variety of different avionics system modules, such as a signal data computer, an advanced signal data computer, a data bus recording module, a crash survivable memory unit, a removable memory module, a cockpit voice recorder, a cockpit video recorder, an analog sensor acquisition unit, an engine monitoring module, a terrain awareness warning system, a computer module, or a controller module. Each module 251, 252, 253, is housed in a housing 254, 255, and 256. The housings 254, 255, and 256 each comprises surfaces having pseudo fractal structures, as described above. Additionally, at the surfaces where the housings fit together 257, the housings have conjugate pseudo fractal structures. The assembly of the coupled sub-housings 251, 252 and 253 are coupled to the main housing 250 using a plurality of dampeners 259. These dampeners reduce the transmission of vibrations from the outer housing 250 to the inner housings 251, 252, and 253 and may comprises, for example, elastomeric structures or other dampening couplers.

FIG. 2I illustrates a close up of region 258 illustrating such conjugate pseudo-fractal structures. In this embodiment, module 252 comprises a housing having a plurality of pseudo fractal protrusions 258, 259, 260, and module 253 comprises a plurality indentations 263, 264, and 265. In this particular embodiment, the pseudo fractal structure has a repeating rectangular pattern. The pseudo fractal structure comprises a sequence of rectangular protrusions 258, 259, and 260. In some embodiments, each protrusion in the sequence may have a different width (i.e. duty cycle) than the other protrusions, further distributing the resonant frequencies of the structure. Each protrusion 258, 259 and 260 comprises smaller scale protrusions 261 and 262. These small scale protrusions may also have a predetermined width sequence. In various embodiments, the width sequence may be similar to or different than the sequences at other scales. Additionally, in this embodiment, the vertical surfaces of the pseudo fractal structure are planar to facilitate assembly during manufacturing.

Some embodiments of the invention comprise integrated avionics systems. These embodiments enable transfer of large amounts of data to ground stations and reduced power and weight requirements. Typical prior avionic systems are affected by the distributed topology with limited communication bandwidth and connectivity (slow speed data buses) and limited sensor data fidelity) low sampling rate from 1 to 4 Hz). The limited connectivity and communication bandwidth forces each of the Weapon Replaceable Assemblies (WRA) to contain a processing element and control logic making the avionic systems over redundant. Embodiments of the invention replace loosely coupled WRAs into Function Centric (FC) WRAs with high speed internal connectivity and highly shared resources including processing memory and I/O.

These embodiments provide various benefits, such as the ability to offload some of the on board processing to ground processing and significantly reduce weight volume and complexity of the WRA architecture. Another aspect of some embodiments implementing such processing separation is the ability rapidly transfer the flight data to ground station by means of high speed wireless data download hardware integrated with the FCWRA. Another aspect of maintenance operation is ability to transfer flight data rapidly for immediate after flight evaluation. Additionally, some embodiments operate like a network appliance with an unique IP address and web application being a part of the Operation Flight Program (OFP). Some embodiments utilize wireless connectivity FCWRA to establish communication with a maintenance operation and provide transparent access to flight data without distance limitations.

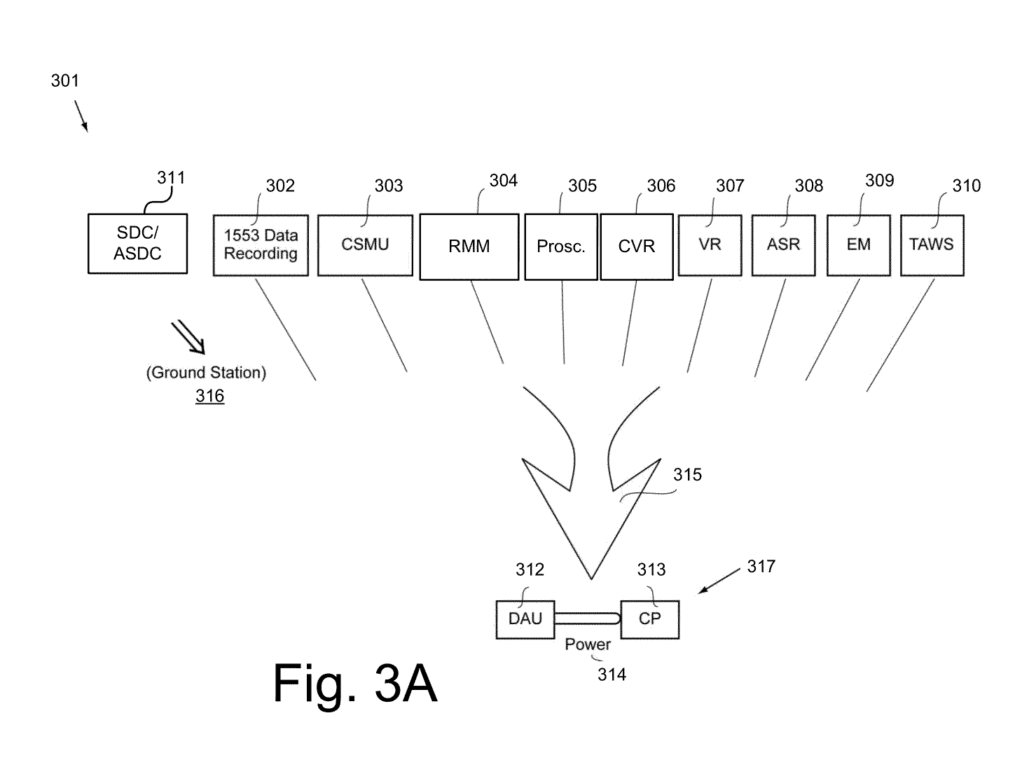

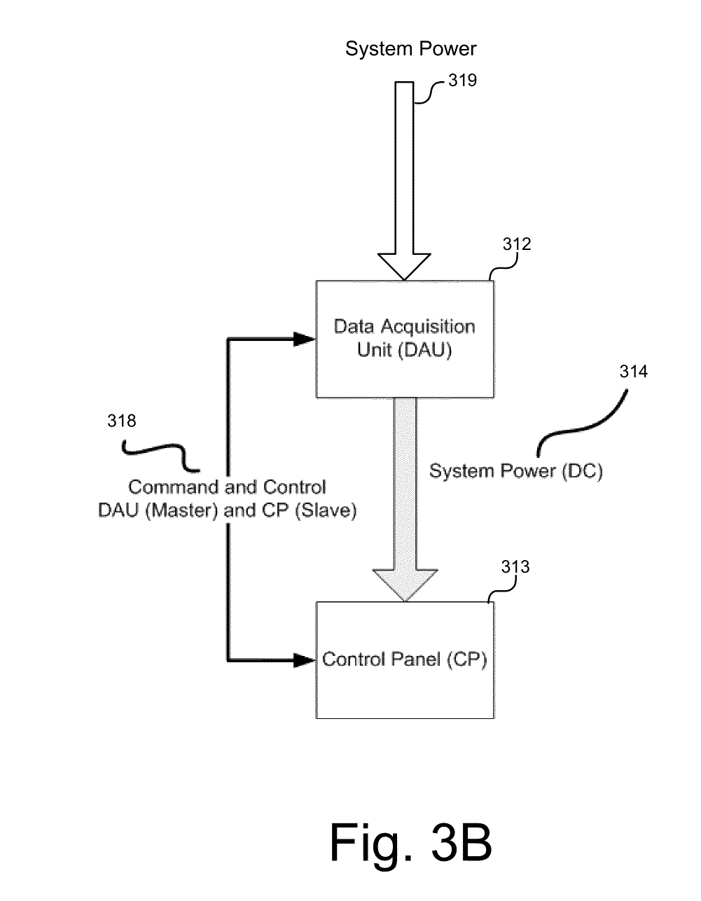

FIG. 3A illustrates such a function-centric data system (FCDS) architecture implemented in accordance with an embodiment of the invention. In this embodiment, a plurality of monitoring functions are integrated into a single data acquisition unit (DAU) 312. The control of the monitoring functions is integrated into a control panel 313. Both processing power and electrical power 314 is provided from the DAU 312 (which may be housed in an avionics bay, for example) to the control panel 313 (which may be housed in an aircraft's cockpit, for example). The power connection 314 allows power to be provided to different functions as needed, reducing power requirements that would otherwise be present by separately powering each module.

FIG. 3A illustrates a number of avionics monitoring modules that may be integrated in DAU 312 in various embodiments. These monitoring functions include (a) a 1553 bus data monitoring module 302 that records the data on the external system bus at predetermined intervals; (b) a cockpit voice recorder 306 (CVR); (c) a video recorder 307, such as a cockpit video recorder that is situated to record a view similar to that of the pilot; (d) an analog sensor recorder (ASR) 308; (e) an engine monitoring (EM) system 309, and other common avionics monitoring modules. In addition, the DAU 312 comprises processors and other modules to implement and utilize these functions and data sources. For example, the DAU 312 may comprise (a) a crash survivable memory unit (CSMU) 303 that stores select data, such as voice, data bus recordings, in a time limited manner to provide a record in the case of aircraft failure; (b) a removable memory module (RMM) 304 that stores maintenance data, flight data, or other mission data that can be loaded and unloaded in a removable manner; (c) a system processor—such as reduced instruction set computer (RISC) processor 305 that controls system operations and performs the computations for the other system modules; and (d) a signal data computer or advanced signal data computer (SDC/ASDC) 311 that is responsible for calculating exceedences from data received from monitoring systems and sensors, and compressing this data so that is may be used by other systems. Additional embodiments may include further modules, such as a mission data loader (MDL), a laser or radar altimeter, and a midair collision avoidance system (MCAS).

The DAU 312 further implements a link to a ground station 316 from the SDC/ASDC module 311. In some embodiments, monitoring algorithms are relegated to the ground station 316. For example, rather than providing the grounds station 316 with brief snapshots (for example, 4 Hz data samples) or exceedence counts, the module 317 can provide the ground station 316 with higher data rate samples (for example, at or greater than 32 Hz). This allows the ground station 316, which has access to more stationary processing power and larger databases than is available to the aircraft, to conduct monitoring algorithms. In some embodiments, these modules are CSMU compliant to ED-112 certification, which includes a 1100° C. 1 hour-high temp test, and about 250° C.-longer time (^{˜}8 hours) test, as well as 3400 g-impact, and a high water pressure test of 160 MPa. In other embodiments, the modules are ED-155 compliant, which are less rigorous standards.

FIG. 3b illustrates the master/slave relationship between the DAU 312 and the control panel (CP) 313. In one embodiment, the FCDS system comprises of a DAU 312 and a control panel 313 for the DAU 312. These modules may be physically separate in the aircraft. For example, the DAU 312 may be located in an avionics bay—such as in an under floor compartment, and the control panel 313 may be located in the cockpit. In the illustrated embodiment, the control panel 313 is a passive device to process the commands from DAU 312. In some embodiments, it reduces the processing burden of DAU 312 by handling menu display, BIT information processing, self-health monitoring, and hosting Crash Survivable Memory Unit (CSMU). The DAU 312 receiver power directly from the aircraft 319 and supplies power to CP 314, to minimize the aircraft circuit breaker installation and also to minimize the power by monitoring the activities of CP and also controls the status of CP, e.g. while in air the CP has to be turned off. The intelligent power control and processing power scheme 318 minimizes the aircraft wiring requirement and power consumption by controlling when and which functions are accessible during operations. In the illustrated embodiment, the control panel is powered 314 via the DAU 312. For example, the communications wiring between the DAU 312 and the control panel 313 may be used to provide a DC power to the control panel 313, or additional lines may be installed between the DAU 312 and control panel 313. Accordingly, the control panel does not need a separate connection to the aircraft avionics powering system. Additionally, the DAU 312 is configured to control when the control panel is active and accessible.

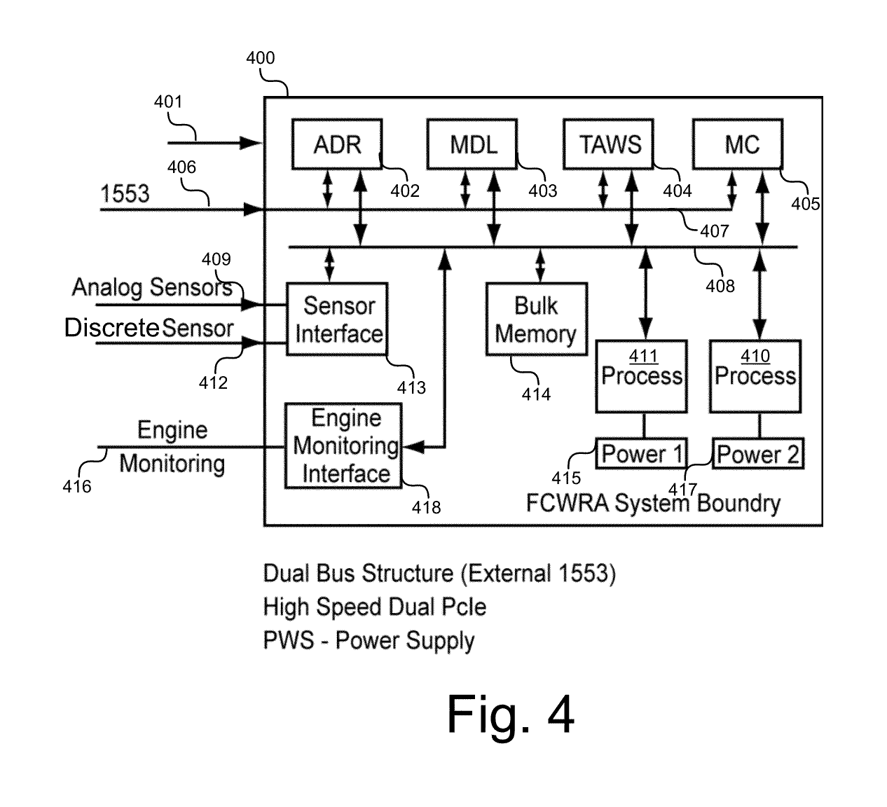

FIG. 4 illustrates an embodiment of a function centric avionics data system—for example, a function centric weapons replaceable assembly (FCWRA). The FCWRA 400 comprises a power interface 401 configured to receive power from a power supply. The assembly 400 further comprises an external bus interface 406—for example, a 1553 bus connection. The external bus interface 406 is coupled to a first internal bus 407, which may be the same type of bus as the external bus 406. The assembly further comprises sensor interface connections 409 and 412. For example, the sensor connections may comprises one or more connections for analog sensors 409 and one or more connections for various discrete sensors 412. The sensors connect to an internal sensor interface 413 that interfaces with a second internal bus 408—for example, a PCIe or other high speed bus. The assembly 400 further comprises a connection for an engine monitoring system 416. An internal engine monitoring interface 418 interfaces with the second bus 408. In additional embodiments, the system 400 may comprise other interfaces, such as weapons interfaces, external sensor interfaces, other communication interfaces, other bus interfaces, and other monitoring system interfaces.

The FCWRA 400 further comprises a plurality of internal processors 411 and 410. The internal processors 411 and 410 provide function redundancy to increase system reliability. To further improve reliability, the processors are coupled to redundant power supplies 415 and 417 and redundant connections to internal bus 408. A bulk memory 414—for example, a crash survivable memory—is coupled to the second bus 408 for communication with and control by the processors 411 and 410. The assembly 400 further comprises various avionics modules, such as ADR 402, MDL 403, TAWS 404, and MC 405. These modules are coupled to the first bus 406 to communicate external avionics systems. The modules are further coupled to the second bus 408 to communicate with other system modules, such as processors 411 and 410. In further embodiments, the modules do not contain their own processors or bulk memory (excepting registers or other common operational memory), rather all processing of their functions and use of bulk memory utilizes the shared resources 411, 410, and 414. Accordingly, rather than being simply a standard avionics system, they are modified to provide only functionality that is not otherwise present on the system.

The processors 411 and 410 may be configured such that one processor is a back-up and only activates if the first processor is damaged or otherwise non-operating. The processors 411 and 410 are configured to control the operations of the modules 402, 403, 404, and 405, allowing them to be powered and use processing power only when necessary. For example, in some embodiments, the processor 411 and 410 are configured to implement task oriented power distribution. For example, the processors 411 and 410 may receive information regarding various flight phases (such as, taxing, lift off, climbing, cruising, and landing) and power the modules 403, 403, 403, and 405 at the necessary times. For example, if the system included a weight on wheels monitoring module, this module might only be activated during taxing, lift off, and landing. In additional embodiments, the processors 411 and 410 may implement various time sharing methods, such as time division multiple access, where each module is allowed to write to bulk memory 414 for data recording at different times. In further embodiments, the activation may be pilot controlled, for example, the pilot may control the coupled control panel to dim when using night vision. In addition to serving as a back up processor, one of the processors—for example, processor 2—may be configured to control some of the modules if the number of active modules exceeds a single processor's capabilities.

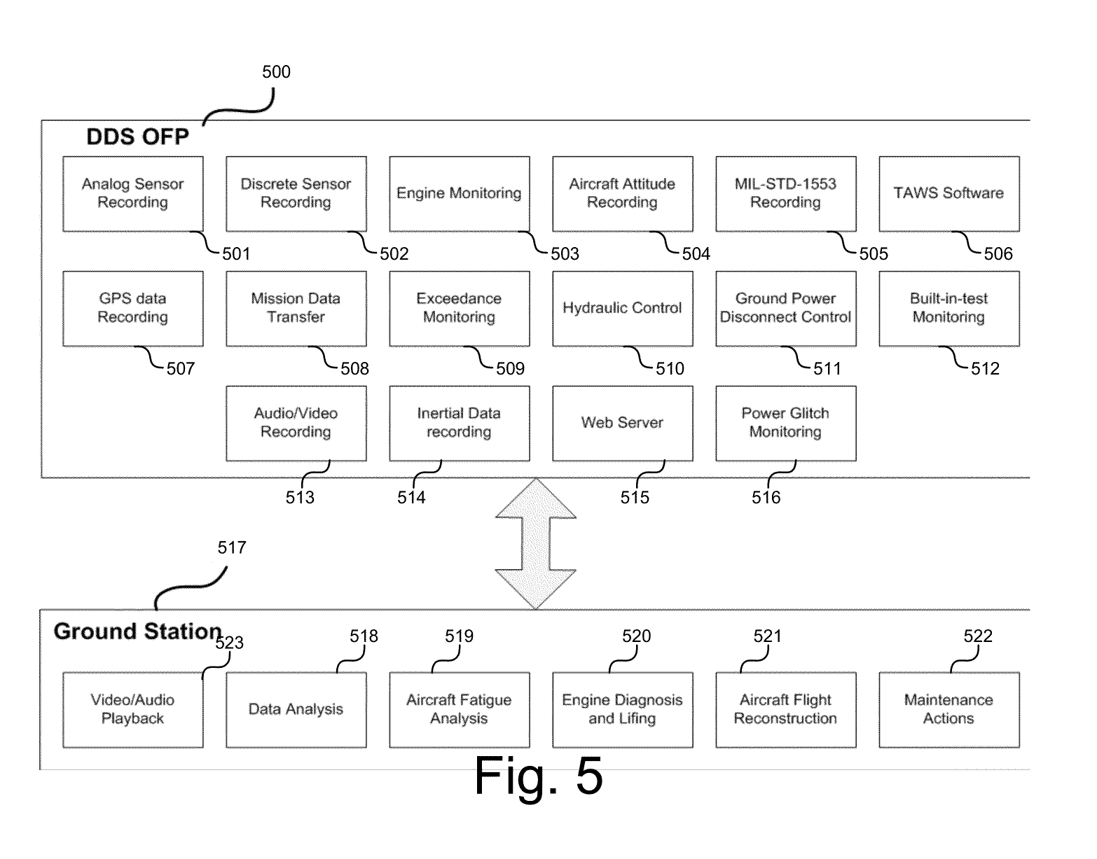

FIG. 5 illustrates an operational flight program 500 that may be embodied on a FDS implemented in accordance with an embodiment of the invention. The OFP 500 is configured to interface with a ground station 517 to provide various data and analysis to the ground station. In the illustrated embodiment, the OFP handles analog sensor recording 501, discrete sensor recording 502, engine monitoring functions 503, aircraft altitude recording 504, data bus recording 505—such as MIL STD 1553 bus recording, TAWS software operations 506, GPS data recording 507, mission data transfer 508, exceedence monitoring 509, hydraulic controls 510, ground power disconnect control 511, built-in-test monitoring 512, audio/video recording 513, inertial data recording 514, power glitch monitoring 516, and implements a server 515—such as a web server—for ground station 517 to access data from the OFP 500. In other embodiments, some of these functions may not be present, or other avionics related functions may be included in the OFP 500.

In some embodiments, the OFP 500 provides recorded data to the ground station 517. The recorded data can be used in the ground station 517 to perform functions such as video/audio playback 523, data analysis 518, aircraft structural fatigue analysis 519, engine diagnosis and lifing 520, aircraft flight reconstruction 521, and other maintenance actions 522.

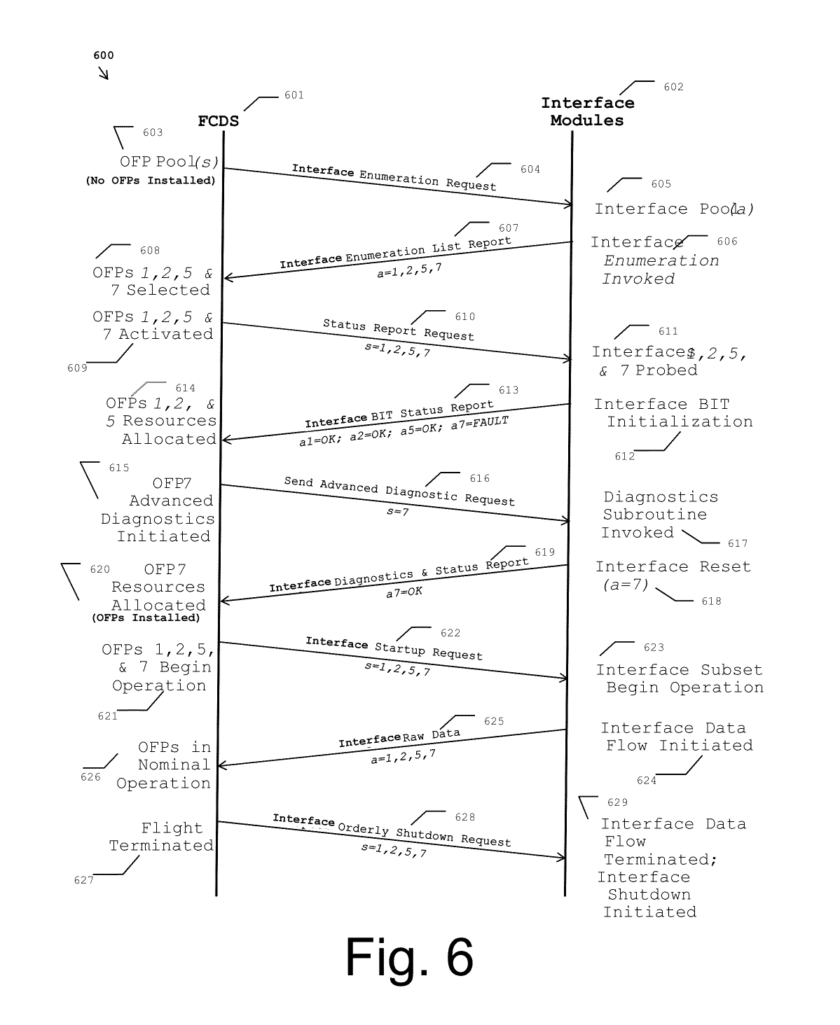

In some embodiments—for example, as illustrated in FIG. 4—function centric data systems may be provided with a plurality of interfaces. These interfaces may allow the function centric data system to interface with various external systems. A general function centric data system may be configured to be installed a variety of different platforms, and may according have a plurality of adapters that may or may not be needed for a given application. In some embodiments, function centric data systems are configured to automatically configure which interfaces are active during a given use. FIG. 6 is a transaction diagram describing an automatic configuration aspect of the present invention wherein an interface initially shows a fault that is corrected by an interface reset. One embodiment of the present invention provides avionics command and control (e.g., mission computers, mission data loaders) and monitoring systems (e.g., flight data recorders)—for example, as illustrated and described in FIGS. 3-5—with the ability to automatically and/or autonomously reconfigure themselves with the aircraft environment (i.e., platform) changes configuration (e.g., sensors are changed from the analog to digital variety), or when the system is installed in a new/different aircraft.

This is accomplished by high operational flight program (OFP) reconfigurability enabled by dynamic sensing and OFP selection. Essentially the system 601 includes an OFP pool 603 of all available OFPs, which comprise software and/or firmware, and a plethora of hardware interfaces suitable for interfacing to a wide variety of aircraft platforms. When FCDS avionics unit 603 is installed 600 into an aircraft (or the aircraft platform changes configuration), it begins to scan (i.e., probe) the supersurrogate's physical configuration and then the platform's configuration by first enumerating the interfaces 602 attached to the core/stock avionics unit, and then enumerating and installing the appropriate OFPs dynamically, without human intervention. The interfaces and OFPs are then tested for integrity and functionality. If any are found to be defective, warning messages are generated and delivered to the pilot and/or ground crews. If the errors are severe enough to prevent safe flight, the flight startup sequence is aborted and the pilot crew notified of the failure. An example of these processes can be found in FIG. 6.

Referring to FIG. 6, in an example aircraft platform installation 600, the FCDS 601 is assembled by adding four (4) interfaces 602 to a base/stock unit. Initially, no OFPs are installed; however the entire OFP pool (s) 603 is available for selection.

Upon application of system power, an interface enumeration process 604 begins and the interface pool (a) 605 is scanned in order to determine which interfaces are physically installed. Then, an interface enumeration process 606 is invoked which generates a list 607 of installed interfaces, that are then selected 608 for activation and activated 609. The base unit then requests the status 610 of the installed interfaces (in this example, interfaces 1, 2, 5, and 7 are found to be installed). The installed interfaces are then probed 611 and built-in tests (BITs) 612 are initiated. The results of the BITs are reported 613 to the base unit (surrogate) and OFP resources are allocated to functional interfaces 614. In this example, interface #7 is found to have a fault and advanced diagnostics contained in the corresponding OFP 615 are requested 616. The offending interface is tested 617 and the appropriate corrective action is taken, if any is possible. In this example, interface 7 is “reset” 618, and its status 619 is reported to the surrogate. Since the interface was successfully restored to operation by the reset, its corresponding OFP resources are allocated 120.

Once all interfaces have their resources allocated, the OFPs begin operation 621 and all installed interfaces are brought on-line 622. The interfaces then begin their nominal operation 623 and (pre)flight data begins to flow from/to them 624. This raw data 625 is then received and processed by the appropriate OFPs, which are now operating in their nominal modes of operation 626. Once the sortie (i.e., flight) is terminated (e.g., the plane lands) 627, an orderly shutdown of the installed interfaces is requested 628. At this point, interface data flow is terminated and the interfaces are shutdown 629.

Once the FCDS 601 (one of the myriad of configurations of the supersurrogate) is formed by the successful configuration of its dynamically-installed/invoked OFPs and physical interfaces, the FCDS 601 then begins to probe the aircraft platform to determine the onboard electronics installed. In a process similar to that detailed in FIG. 6, the avionics unit proceeds to complete flight configuration and calibration operations by enumerating, enabling (and disabling, if necessary), testing and operating the platform's various subsystems. Once this process is complete, flight may begin.

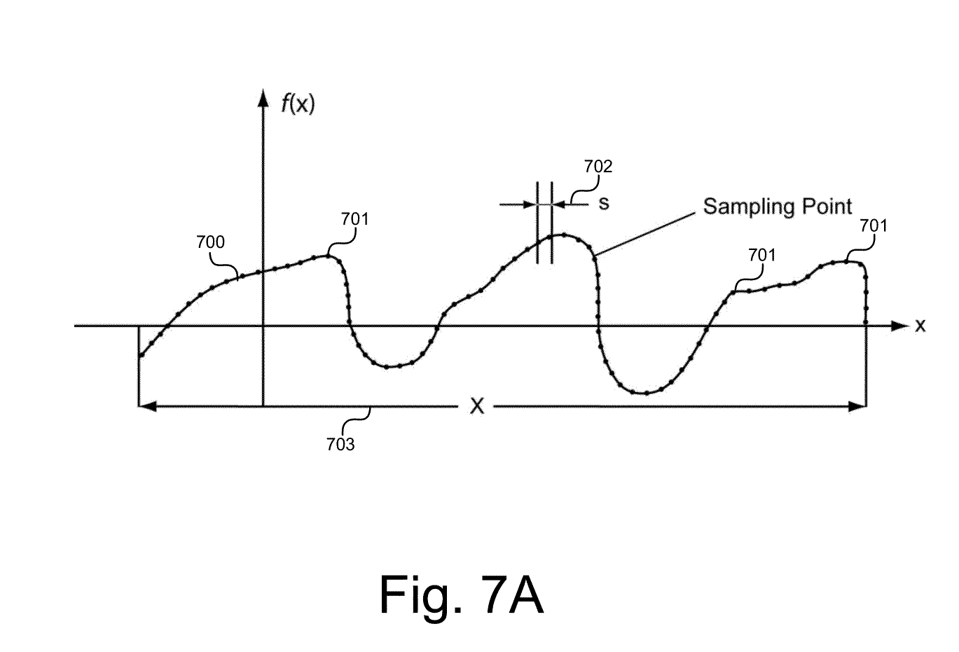

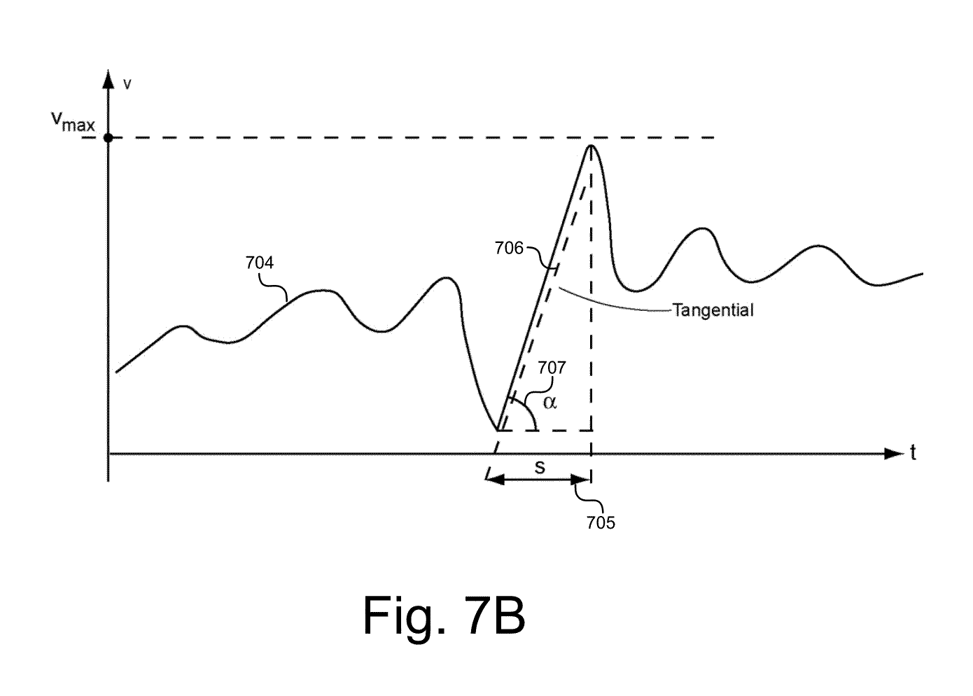

Some embodiments of the invention are configured to sample data from various data sources, such as the data sources described with respect to FIG. 5. These data samples are then provided to a ground station for processing—for example, for maintenance, clearing aircraft for future operation, and training. FIG. 7A illustrates a generalized data output 700 over an interval Δx 703. This data output 700 may represent the output of various sensors or monitoring systems connected to a data acquisition unit implemented in accordance with an embodiment of the invention. This data is sampled to form a set of sample values 701 at some sampling rate 702.

A number of inequalities known as the Bernstein inequalities have been formulated as a consequence of Fourier theory, in general, and the Shannon sampling theorem, in particular. These inequalities may applied to the sampling frequency increasing problem in the context of FCDS. In particular, as the number of samples 701 of a data output 700 grows, the volume of the data increases. However, with fewer samples, the usefulness of the data decreases. The number of degrees of freedom (DoFs), or so-called Shannon number, is the number of uniform discrete function values 701 (so-called sampling points), sufficient to uniquely determine a function f(x) 700, within some finite range, X, 703 with a sampling constant s 702.

The sampling constant, s, 702 is distance between consecutive sampling points 701. The sampling constant 702 is equal to resolving element of this function 700. The sampling theorem further dictates that with knowledge of the sampling function values 701, the smoothest function drawn through those points 701 is the function with limited spectrum, Δf, such that: s=1/Δf. The maximum frequency: f=|Δf| is called sampling frequency.

In some embodiments, the sampling constant used for data collection from a given data source is determined using Bernstein inequalities applied to the data under considerations of the type of indication desired from the data.

An example of sampling according to desired information content is illustrated in FIG. 7B. In this embodiment, a data source provides a velocity measurement (illustrated in one dimension for purposes of explanation). The desired information is whether the acceleration (the slope of the velocity) exceeds a predetermined value. According, the Bernstein inequality is applied to the non-negative function 704, v(t), where t—time and v—velocity in one direction. According to FIG. 7B, the maximum value of time differential 706, equal to tan α, where α is inclination angle 707 of tangential to function v(t), cannot be larger than vₘₐₓ/s=vₘₐₓ·f:

$$\vert \frac{d v}{d t} \vert = \vert a \vert \leq {v}_{max} \cdot f \qquad ( 2 \text{-} 1 )$$

where vₘₐₓ is the maximum velocity value, while f-sampling frequency. Therefore, the sampling frequency, f, limits maximum acceleration, a, value, according to Eq. (2-1). Accordingly, in some embodiments, the maximum reportable acceleration value is predetermined and the sampling constant is selected to be greater than or equal to the sampling constant required to report such acceleration values.

Eq. (2-1) is the Bernstein inequality applied to the practical problem of avionics, which is monitoring/reporting about some flight function (or, other avionics function), based on digital data which are characterized by sampling frequency, f, and maximum velocity value, vₘₐₓ. This example is limited to only one direction of velocity (since v(t)-function is non-negative) which is the natural feature in the case of any avionics platform. (Such platform cannot suddenly change direction of motion without causing major flight failure.) However, we can generalize this equation also to negative function values; then vₘₐₓ is replaced by velocity variation |Δv|. Further generalization can go to platform velocity components: vₓ, v_{y}, v_{z}, as well as to angular functions characterizing other three DoFs of aircraft, such as: roll, pitch, and yaw; then v is replaced by angular velocity, w. Other functions can be angle of attack (or, climbing angle), replacing x-coordinate, as well as altitude (z-coordinate), pressure, etc. Also, other x,φ generalized coordinates can characterize control surfaces (flaps, aileron, and rudder). In any case, equations analogous to Eq. (2-1) may be formulated, allowing generation of the relevant inequality for some generalized acceleration, providing a sufficient sampling constant for the desired reporting values.

In a particular embodiment, a function centric data system samples data at 32 Hz and records all the data. The engine related information can be used to analyze the engine health monitoring using the following information: fuel flow, throttle position, engine temperature, high pressure engine RPM, low pressure engine RPM, ambient temperature, barometric information, and so on. The engine health monitoring algorithm—for example, the Rolls-Royce computational fluid dynamic (CFD) algorithm—was used in legacy data recorders because it did not have enough storage to record all the incoming data. However, since the information is only needed for engine maintenance purpose and FCDS has enough storage to record high fidelity data (32 Hz), the engine monitoring algorithm can be run in ground station with FCDS high fidelity data. Another shortfall using the engine monitoring algorithm in legacy recorder is that the incidents of engine can be easily missed since the recorded data will not have all the trends of what had happened in flight. The FCDS records all the data at all the time therefore very comprehensive analysis is possible in ground station, including engine health monitoring, aircraft structural fatigue analysis, and sensor health monitoring and troubleshoot. Additionally, this allows upgrades to algorithm and other analysis software at the ground station without recertifying the avionics systems.

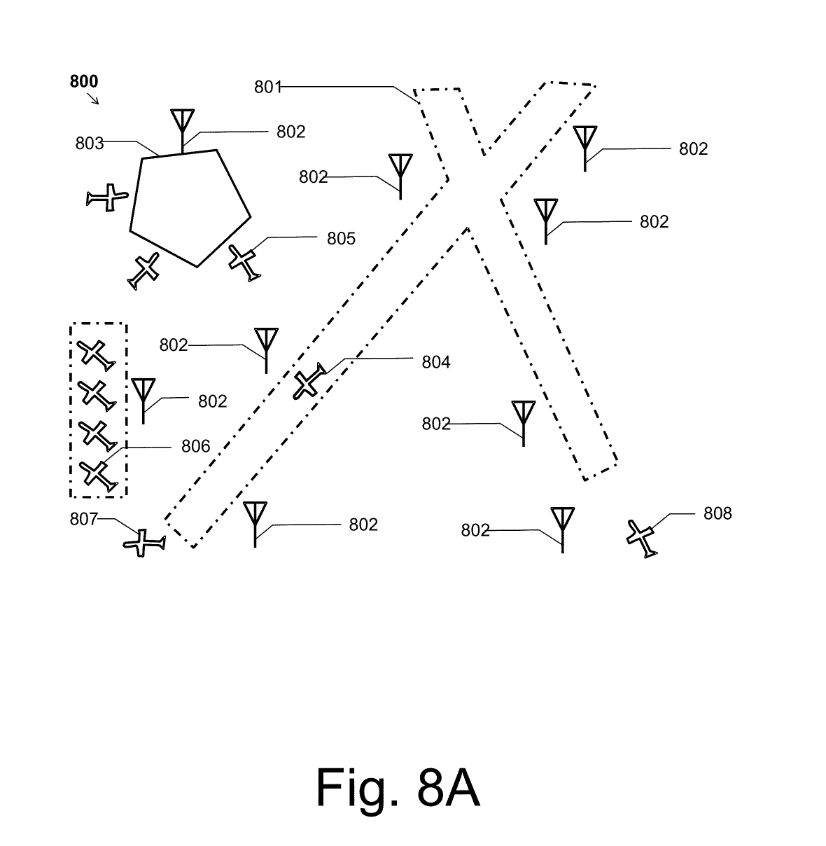

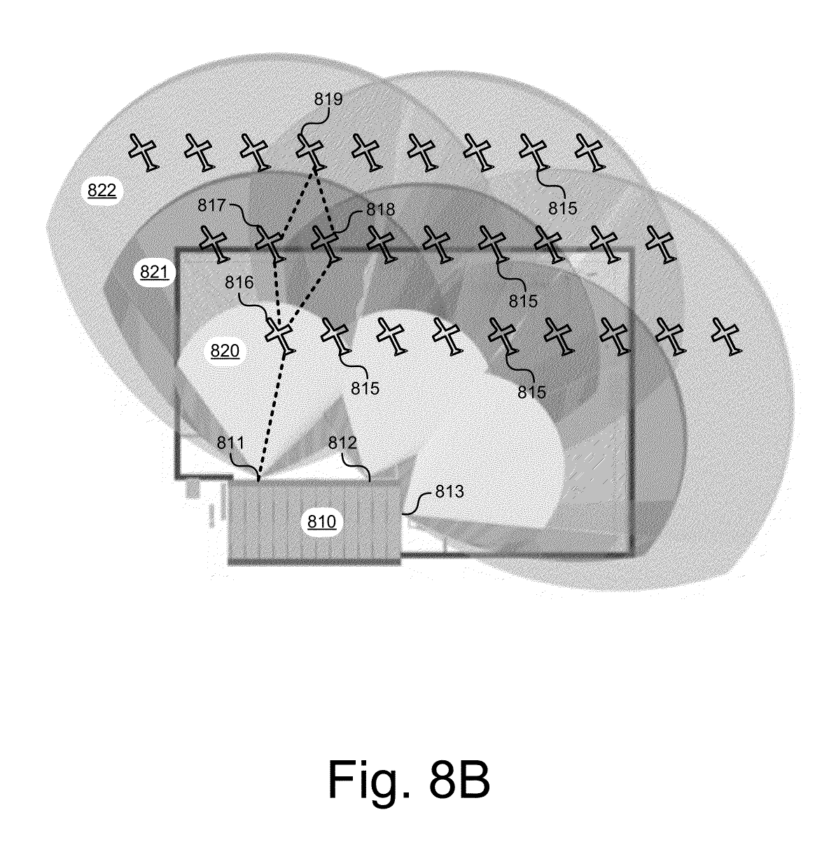

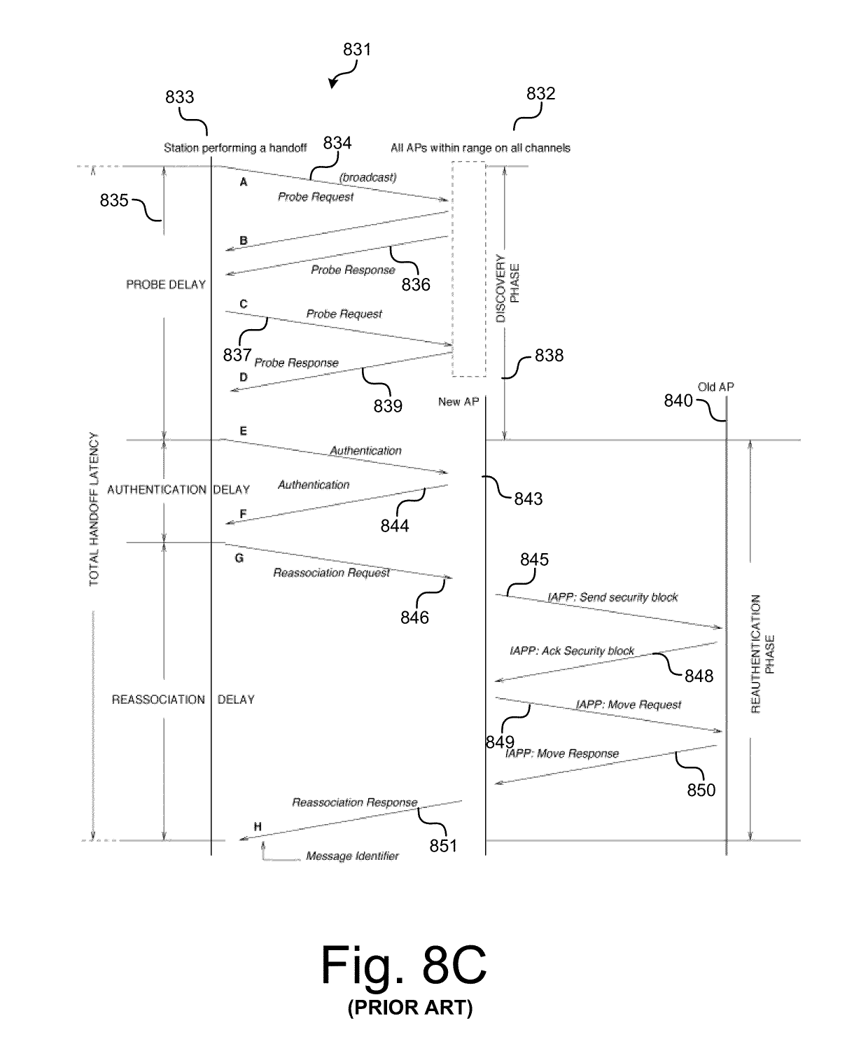

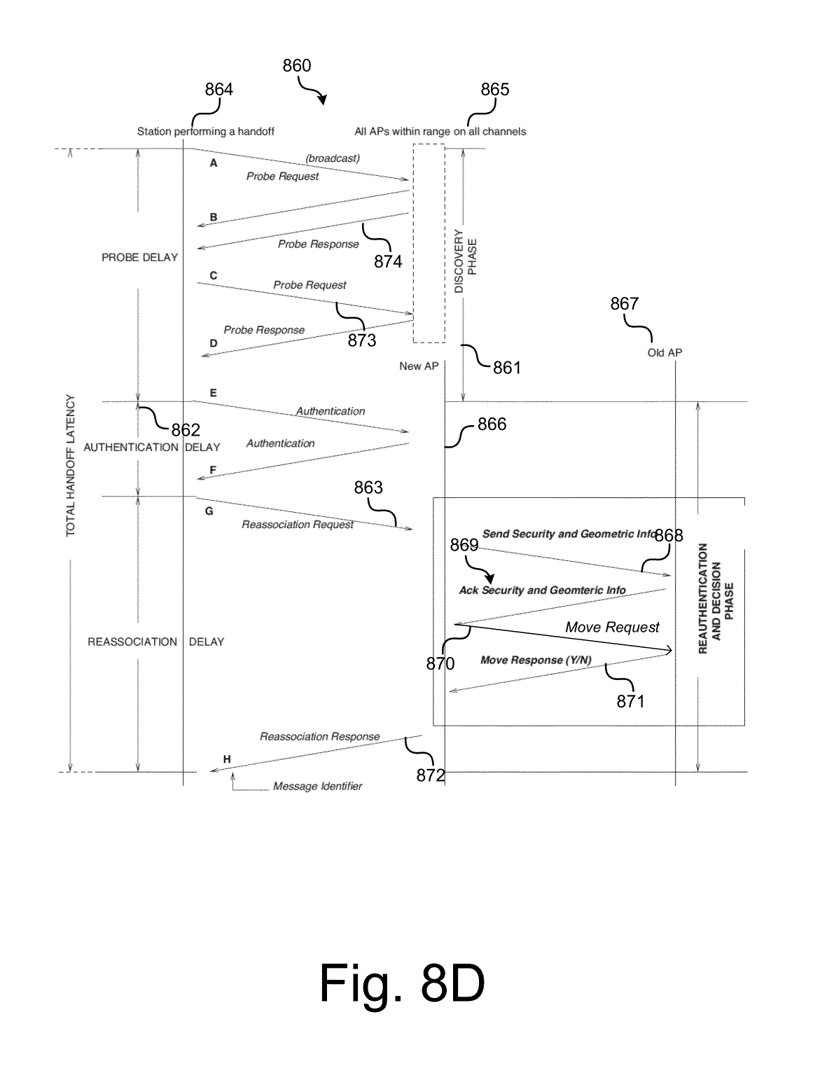

In some embodiments, the function centric data systems provide data to the ground stations using a wireless transfer protocol—for example, a 802.11x protocol, such as 802.11n. In one embodiment, the data transfer from the aircraft to the ground station occurs when the aircraft lands and begins taxiing. FIG. 8A illustrates an airfield with deployed antennas to allow wireless data downloading from taxiing and parked aircraft. In this embodiment, the airfield includes a movement area 810, including runways and taxiways a ramp with parked aircraft 806, and a ground station terminal 803. The airfield has a plurality of antennas 802 disposed throughout the airfield. Each antenna is provided with geographical location information for itself and for other antennas in the field (for example, through GPS systems or triangulation systems). In this embodiment, the aircraft 804 communicates with the antenna with the best available antenna (measured through signal strength, data rate, or other communications parameters) as it travels through the airfield.

In some embodiments, the sampling constant is further determined according to throughput requirements. For example, consider VGA-type video data (as most bandwidth-consuming data), obtained from FCDS video recorder, with resolution: 740×480 pixels, RGB-color (24 bits/pixel, or 24 bpp), and real-time (i.e., 30 frames/sec, or 30 fps). Then, the un-compressed video throughput, B, is

B=(740×480)(24 bpp)(30 fps)≈256 Mbs. (3-1)

Assuming moderate data compressing with compression ratio, (CR)=100:1, we obtain, that the compressed throughput, Bₒ, is B/100=2.56 Mbs. Assume that we apply the wireless downloading Wi-Fi radio, or 802.11n radio, with raw bandwidth of 1 Gbs, but with effective bandwidth (after OVH-extraction) of 200 Mbs, or B_{R}=200 Mbs. Assume we need to download 2 hours of this video data, which, is: V=2.56 Mbs×(3600 sec)(2 h)≈18.4 Gb=2.3 GB. Then, the transmission time, T, of this data, is

$$T = \frac{18.4 Gb}{200 Mbs} = 92 sec = 1.53 min , \qquad ( 3 \text{-} 2 )$$

i.e., very short time of wireless downloading. In Table 2, the downloading time, T, is calculated as a function of compression ratio, (CR). In further embodiments, additional compression ratios may be used—for example 250:1 or higher.

TABLE 2
Downloading Time vs. Compression Ratio

| (CR) | 200:1 | 100:1 | 80:1 | 50:1 | 20:1 | 10:1 |
|---|---|---|---|---|---|---|
| T | 46 sec | 1.53 min | 1.9 min | 3.1 min | 7.65 min | 15.3 min |

Referring to FIG. 8A, an illustration of a wireless aircraft data transmission scheme 800, wireless download of information (data) acquired or produced by an avionics unit incorporating features of the present invention can be accomplished via an array of antennas 802 which can be mounted near the ground alongside an airport's runways 801, mounted on its terminal 803, or elsewhere in the airport facilities. This may occur whether the aircraft is landing/taking-off 804, taxiing 807, stored 806, parked 805 at a terminal 803 or even when it is still airborne—either during normal flight or while approaching/departing 808 the airport.

As the aircraft traverses the airfield, the aircraft communications system is handed off between the antennas. The hand off utilizes shared location information to decide the next antenna for the hand off. In addition to the location information of the antenna, the antenna may be a directional antenna. In these cases, some embodiments transmit and exchange their antenna directionality information. This allows both the aircraft 804 and the antennas 802 to determine a velocity vector to project which antenna 202 will be optimal for the next hand off.

In some embodiments, the wireless data transfer from the aircraft to the ground station may utilize multi-hop networking with other aircraft serving as relays to extend the range of the antennas. For example, as illustrated in FIG. 8B, a ground station may be provided with a plurality of directional antennas 811, 812, and 813. These antennas have limited coverage areas determined by gain and power availability as well as the communications systems on the aircraft 815. For example, antenna 811 may have a first range 820 allowing for a first data speed, a second range 821 allowing a lower data speed, and a third range allowing a limited data speed 822. In one embodiment, when a new aircraft, for example aircraft 819 parks near the ground station 810, the aircraft monitors the communication network created among the aircraft 815 and antennas 811, 812, and 813. The communications system exchanges geographical information at predetermined times, allowing the aircraft 819 to determine its location and antenna availability, and its nearest neighbors 818 and 817 in a route to the ground station 810. In addition, in some embodiment geographical antenna directionality information is transmitted as well.

The aircraft 819 generates a routing table incorporating the geographical locations of its nearest neighbors—for example aircraft 817 and 818. This allows the aircraft 819 to generate one or more multi-hop routes to ground station 810—for example, from aircraft 817 to aircraft 816 to antenna 811 and from aircraft 818 to aircraft 816 to antenna 811. In some embodiments, when an aircraft is about to leave the network—for example, if aircraft 817 were about to take off—the leaving aircraft transmits a notification to its neighbors or broadcasts the information throughout the network. The remaining aircraft use this information to update their routing tables. In other embodiments, an aircraft is able to leave the network without informing other aircraft, when the absence is discovered, remaining aircraft update their routing tables.

In some embodiments, the aircraft 815 maintain next hop routing tables. According, a multi hop route is not predetermined, but rather is determined as the packet is forwarded along a series of next-hop routes. In these embodiment, in FIG. 8B, aircraft would only control whether it transmits packets to aircraft 817 or aircraft 818 and would not control whether the second hop is via aircraft 816 or another aircraft. In other embodiments, the aircraft maintain routing table that determine the entire routes to the ground station. These routing tables may be propagated throughout the network at predetermined times—such as when a new aircraft joins the network. This exchange may facilitate rapid creation of a new routing table when a new aircraft joins the network and allow new aircraft to quickly develop their own routing tables.

In some embodiments, the wireless downloading utilizes a modified 802.11 protocol—for example, a modified 802.11n protocol. Currently, wireless access point for IEEE 802.11 relies on simple Inter Access Point Protocol (IAPP) that provides multiple AP authentication methods for multiple AP configurations. The IAPP does not provide efficient handoff methods, but is rather a predominantly manual process. FIG. 8C illustrates the prior art handoff process. In this process 831, the station 833 that will be handed off to a new AP broadcasts a probe request 834. The APs within range on all channels 832 transmit probe responses 836. The station 833 selects an AP from the responses and transmits a second probe request 837. The receiving station transmits a second probe response 839. This process is termed the discovery phase 838 and introduces a probe delay 835 period in the hand off.

After discovery 838, the station 833 and new AP 843 perform an authentication procedure 844. After the new station 843 has been authenticated, then new station transmits a re-association request 846 to the new station 843. At this point, the new station 843 transmits a send security block to the old access point 840. In response the old AP 840 transmits a security block acknowledgement 848. After this, the new station 832 transmits a move request 849 to the old AP 840, which responds with a move response 850. After the move response, the new AP 843 transmits a re-association response 851 to the station 833 and the station begins communicating with the new AP. This procedure does not take into consideration geographical information, antenna directionality, or signal strength.

FIG. 8D illustrates an automated handoff procedure implemented in accordance with an embodiment of the invention. In this embodiment, the handoff procedure 860 proceeds similarly to the 802.11 procedure described with respect to FIG. 8C. Here, the station 864 performs a discovery phase 861 with available APs 865 and an authentication 862 with the new AP 866 in a manner similar to described with respect of FIG. 8C. In some embodiments, the probe request 873 for selecting a new AP 866 is based on the wireless clients 864 using AP antenna characteristics, including directionality and geometric information, to choose which AP 866 is to be used. This allows the client 864 to select which AP of the pool 865 has the best signal reception and most data throughput. The statistics of the signal strength is used as a-priori probability to make correct decision. Since the wireless signal does not have uniform distribution in field, the decision process is not linear. The decision making process is based on the Bayesian based reasoning process with geometrical and antenna characteristics as a-priori information and client collects the actual data to infer with the known conditional probabilities. The antenna characteristic information may be provided to the station 864 in a number of ways—for example, it may be transmitted in the probe responses 874. Additionally, the client 864 may use its own geographical and antenna characteristics in the decision.

Here, however, after the station 864 transmits the reassociation request 863 to the new station 866, the new station 866 transmits geometric location, antenna directionality, and signal strength information along with the security information 868 to the old AP 867. This allows the OLD AP to determine if the client 864 will be connecting an optimal AP. If there is a more optimal AP, the old AP 867 may not grant a move request 871. Prompting a negative response 872 to the reassociation request 863. In some embodiments, the response 871 may include an identification of a better AP for the client 864, which information may be included by the new AP 866 in the response 872. If the old AP 867 confirms that the new AP 866 is acceptable, then the move request 870 may be granted 871 and the new AP 866 may transmit a positive reassociation response 872 to the station 864.

In various embodiments, the network connection between the aircraft and the base station may be used to download flight information from the aircraft and also to upload mission critical information from the mission planning workstation to the aircraft directly, eliminating the need for the “sneaker net.”

As discussed above, some embodiments provide remote access to the flight, maintenance and debugging data. This data may be used in evaluating readiness of an aircraft for service in the case where the aircraft does not have a direct depot support. In some embodiments, the FCDS are provided with a unique IP address and web server application as a part of the Operation Flight Program (OFP). Using wireless connectivity, the FCDS can establish communication with a maintenance operation and provide transparent access to flight data without distance limitations.

Some embodiments implement various server functionality, such as:
1. Web server application running on each FCWRA allowing for remote access to all recorded data as well as variety of maintenance and debugging modes.
2. Unique IP address allocation per FCWRA allowing identifying particular FCWRA when connected to World Wide Web either through a wired or wireless router.
3. Multiple modes of operation including; data download, real-time sensor view and calibration, problem isolation and definition (debugging mode).
4. Unique remote synchronization with the existing FCWRA data base allowing for trending and failure prediction based on the most current data updates.
5. Automatic data transfer speed negotiation from 9 Kbps (cell phone bandwidth) to Gigabit Ethernet.
6. Data broadcasting or point to point communication topology.
7. Secure encrypted data transfer capability through https network.
8. Direct link to Built in Test (BIT) to analyze system failures and guide maintenance to isolate the source of failures.

In some embodiments, FCDS provides Gigabit Ethernet as communication interface as well as wireless interface. Both network interfaces are utilized to access the data and to upload the data. In some embodiments, the Gigabit Ethernet interface provides web interface for data download, system configuration changes, snapshot of sensor information, Built-In-Test (BIT) information (or system health information), exceedences information, and aircraft configuration data (such as tail number, engine number, and weight). The interface uses standard TCP/IP protocol that can be connected to the commonly used routers and switches. In some embodiments, the system also utilizes the connection to the remote sharing server, which may be secure military server to route the FCDS Ethernet traffic to the end-user (or maintainers) that complies with military network security requirements. FCDS hosts web server that provides maintenance, engineering, and daily operational capabilities. There is no restriction to connect the web server from remote site if the network allows the routing to the FCDS web server.

In some embodiments, a remote client connects to the FCDS web server through the remote share server (i.e. network cloud server to establish the connection). Maintainer can view the aircraft status, e.g. exceedences, real-time sensor status, video, and system status information (BIT). Then, without being at the aircraft site, maintainer can diagnose the aircraft status to understand the problem or issues. This remote information enables the remote maintenance when the aircraft is down at the remote site, e.g. cross country mission. When the critical error is observed and the pilot decides to let down the aircraft, there is a need to make a decision to see if the pilot can fly again to the closest site for repair or wait for the maintainer coming to the down site. The remote accessibility of aircraft information to make decision on operation saves time, money, and resources significantly.

For example, the aircraft has the exceedences set and the pilot is not aware of the significance of the exceedences set, the pilot cannot make decision if he can fly or not. The maintainer can look at the exceedences page in the FCDS web page and see if it is engine related or simple one time incident, such as structural exceedence, then can advise the pilot to proceed with either fly to the nearest base or wait for the people to come to rescue the pilot. Also, the system can stream the real-time video for better access the situation with visual cue. The real-time video streaming can be used to understand the pilot status and the visual confirmation of aircraft status.

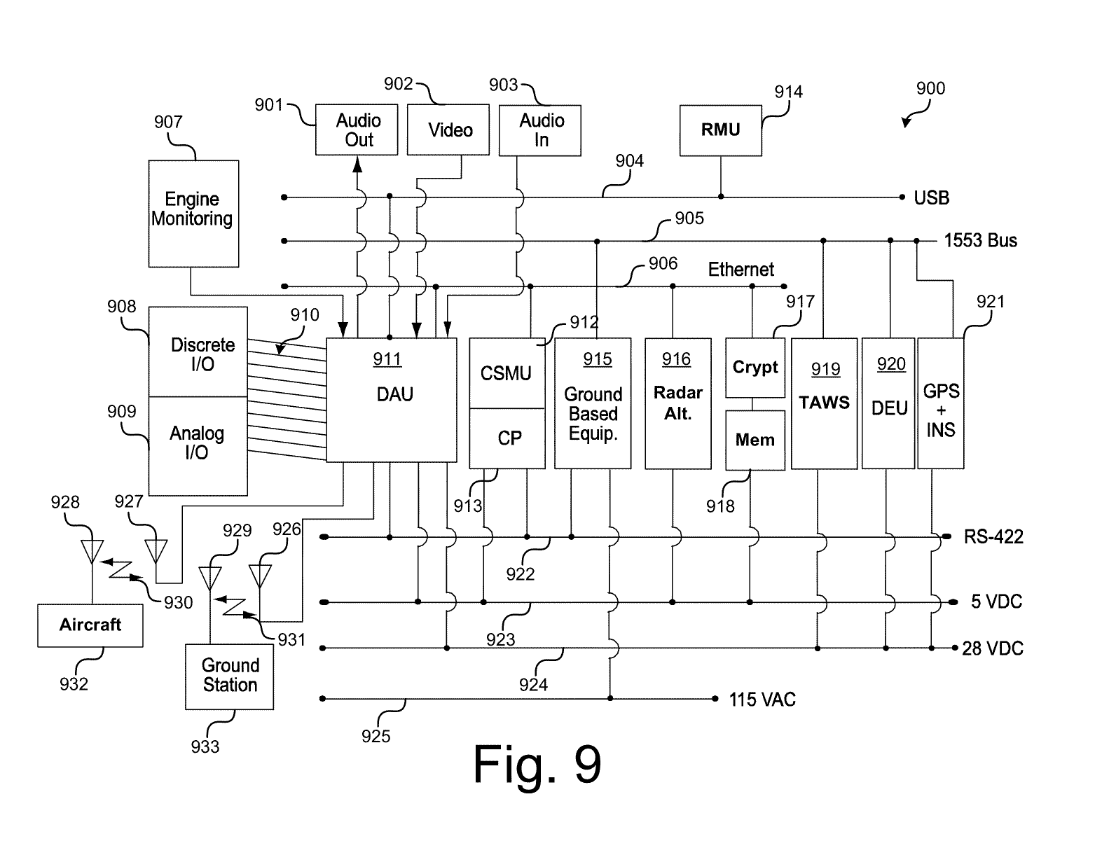

FIG. 9 illustrates a network centric depiction of a general FCDS ICD (Interface Control Drawing), implemented in accordance with an embodiment of the invention. In this embodiment, the Network-Centric FCDS 950 includes: a number of analog audio/video transducers/sensors such as audio (out) 951; video (e.g., NTSC) 952; Audio (in) 953; the point-to-point bus connection such as USB 954; high-speed (serial) interface (HSI) in multi-drop configuration, such as 1553 bus 955; Ethernet connection 956; Engine Monitoring (analog) 957; Discrete I/O 958; Analog I/O 959; Multi-connection 960; between Engine Monitoring Module 957; and DAU 961; Data Acquisition Unit (DAU) 961; Crash-Survivable Module Unit (CSMU) 962; installed at the cockpit panel, for example 974; Ground-Base Equipment 963; Display Electronic Unit (DEU) 964; Inertial Navigation System, including GPS 965; RS422 bus 966; electronic system standard voltage 967; Air Platform Standard Voltage 968; Ground Standard Voltage 969; DAU RF Antenna 970; Ground Station Antenna 971, Ground Station 972; and RF Downloading/Uploading 973. Embodiments may also include an air to air data link 975, and encryption unit 976, and encrypted 977 memory unit 978, a collision avoidance module 979, RADAR and altimeter modules 980, and other common avionics modules. In addition, some embodiments may have air to air links 930 comprising a second antenna and transceiver 927 able to communicate with another aircraft 932 via a corresponding transceiver 928.

In some embodiments, video cameras are disposed on an aircraft to capture various articulated objects, such as instrument gauges, aerodynamic control surfaces, landing gear, or other objects that change in time. These articulated objects have orientations with respect to the video image that are known beforehand. For example, images of instrument gauges have a known orientation with respect to a fixed video cockpit camera. In some embodiments, it is desirable to have a digital recording of analog data as seen by a pilot—for example, a recording of a view of gauges, dials, screens, and windows. For example, a digitization of data received from a cockpit camera that provides a view similar to that of a pilot viewing the cockpit. This data may be used for various purposes, such as crash diagnosis, training, and maintenance. These objects are called kinematic analog parameterized objects (KAPOs), defined as follows:

a) They are two-dimensional (2D), i.e., they are videos.
b) They are On-the-Move (OTM), i.e. they are time varying.
c) Repeatability, they are able to arrive in the same position at different times. (For example, a clock or horizon gauge. The repeatability condition does not necessarily imply a period of repetition, rather that there is a finite range of possible operational positions for the object.)
d) They have a fixed orientation (top, bottom, left, right) with respect to the camera recording them.

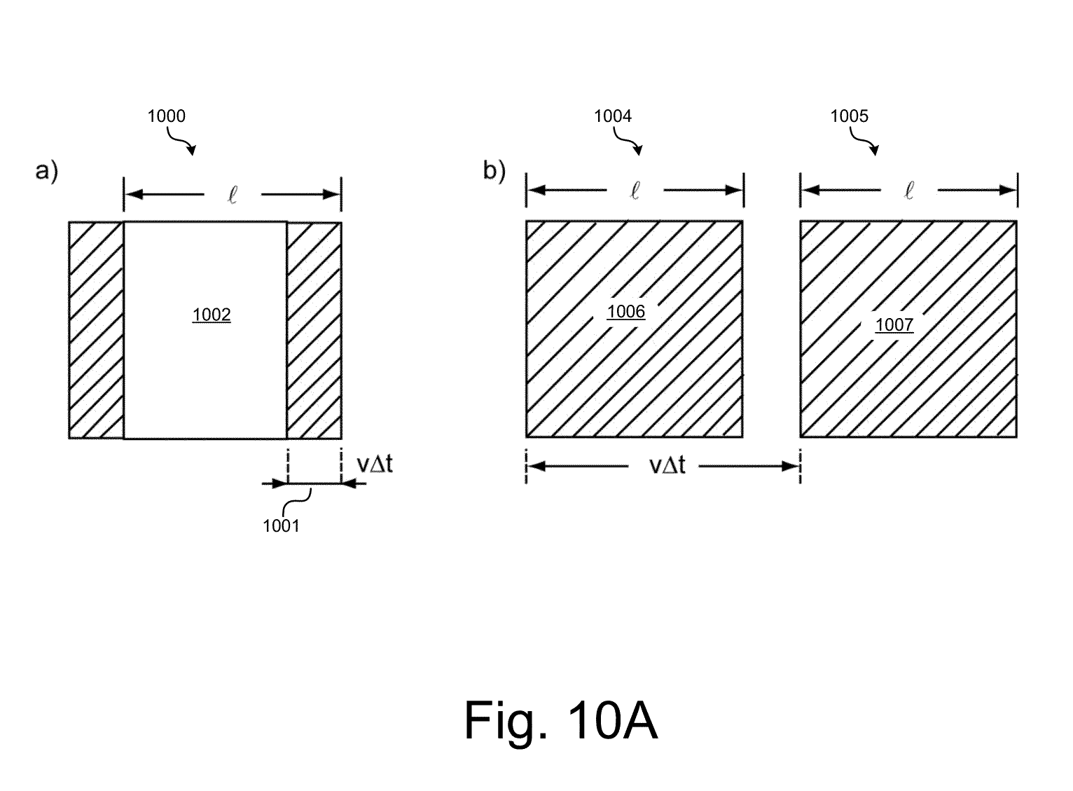

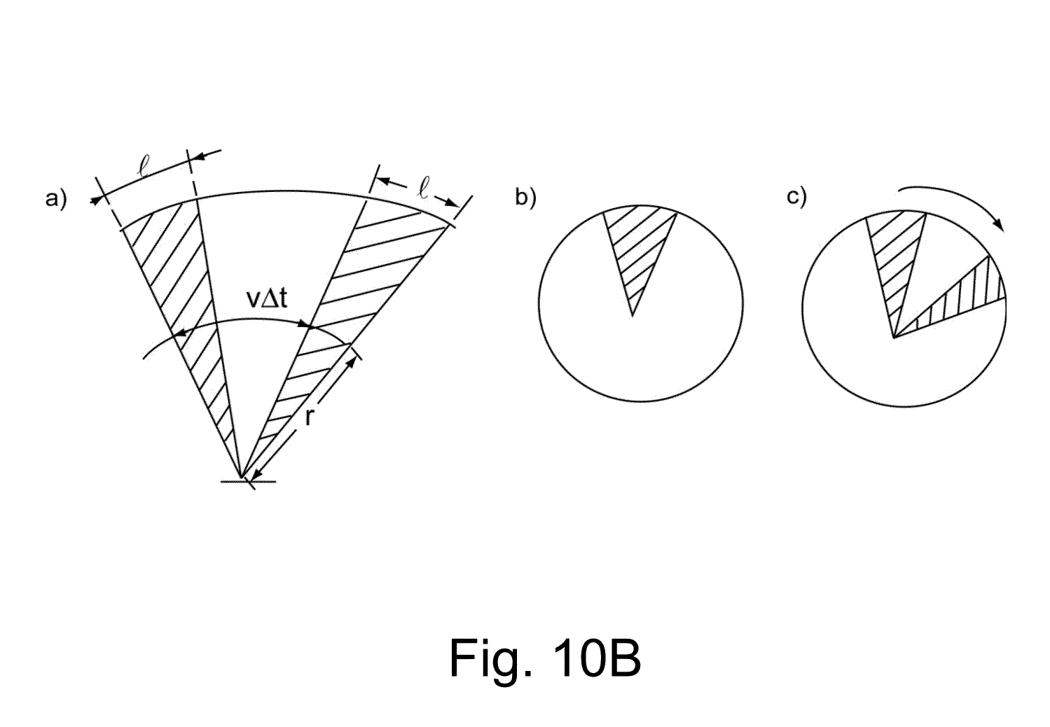

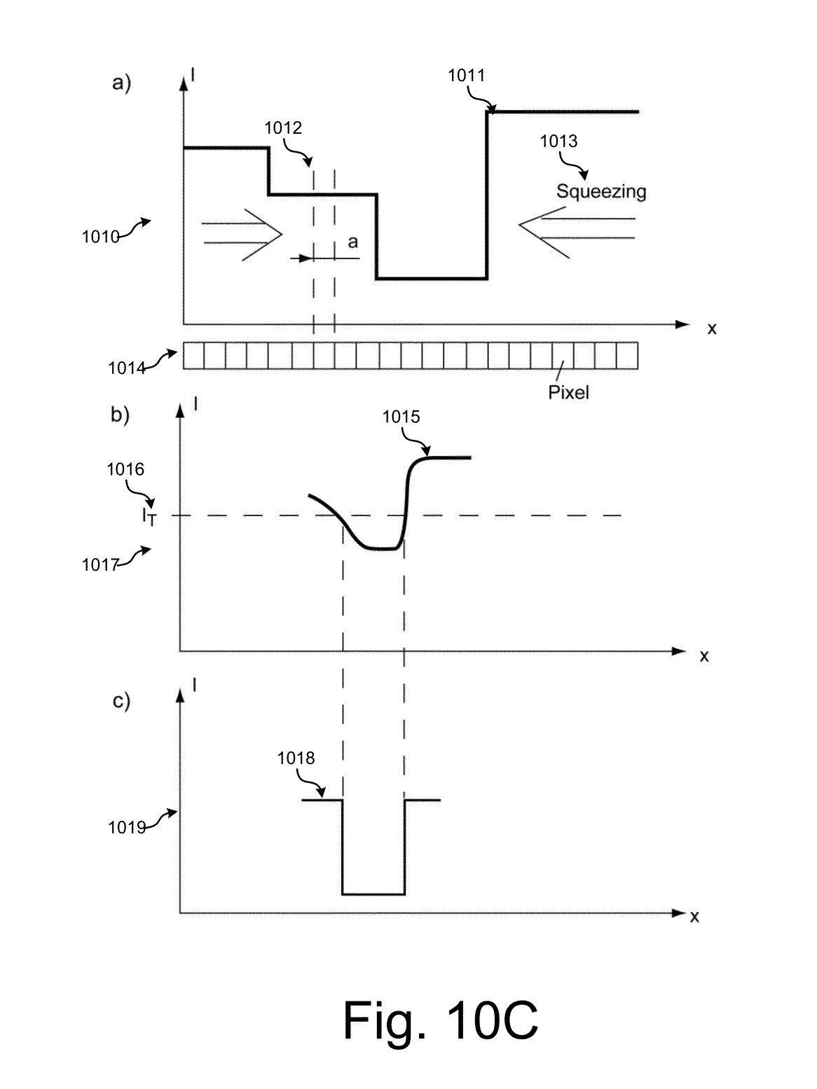

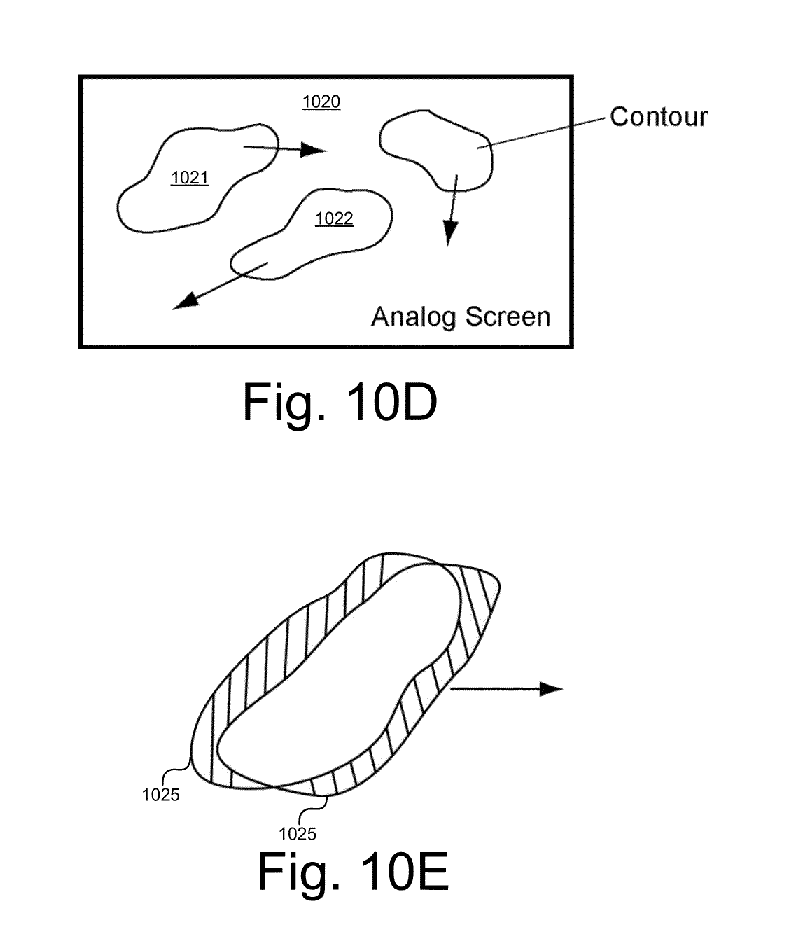

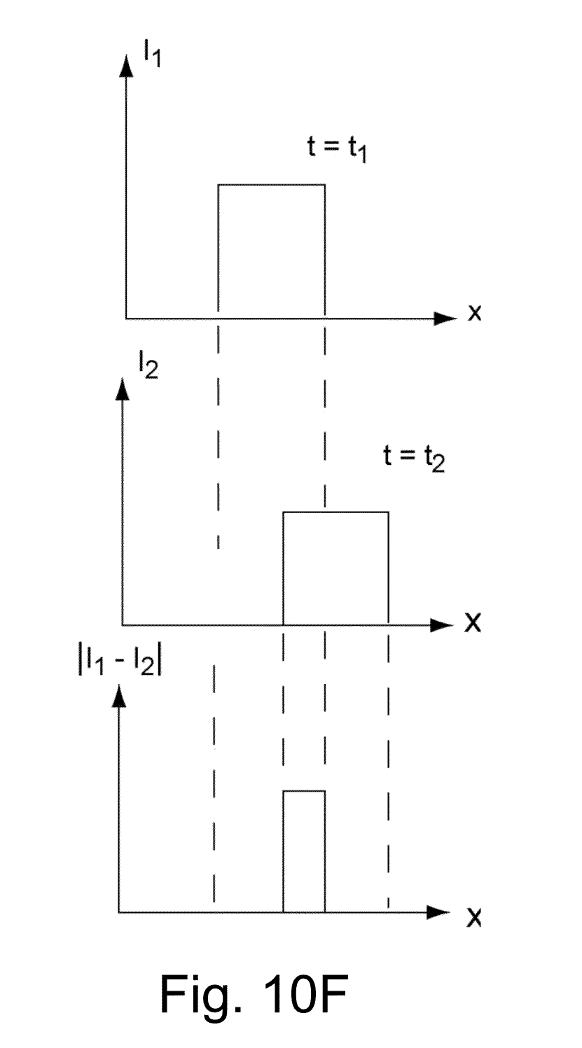

Using Pre-ATR technologies (ATR: Automatic Target Recognition), they can be automatically recognized. (For example, see A. Kostrzewski, et. al., “Ultra-Real-Time Video Processing and Compression in Homeland Security Applications,” SPIE Proc., vol. 6538-68, 2007, the contents of which are incorporated by reference in their entirety.) They can be also recognized by other standard pattern recognitions methods. After pattern recognition, the motion of a given KAPO may be determined. After determining the motion of a given KAPO, the video frame's motion vector flow may be determined. Using the vector flow, a novelty filter process may be applied. For example, FIG. 10A illustrates a novelty filtering technique. FIG. 10A illustrates two scenarios. First, 1000 represents the difference between two frames, where the displacement 1001 of an object between subsequent frames is less than the frame rate, resulting in novel regions (regions that change between ranges) 1002. In the second scenario, the displacement is longer than the length captured by the frame rate. Accordingly, the areas captured by the camera 1006 and 1007 between frames 1004 and 1005 do not have novel regions.

As illustrated in FIG. 10A, the object translation value, ΔL, is

ΔL=vΔt (3-1)

where Δt is counted in frame rate units, Δt₀. For example, Δt₀=33.33 msec=0.033 sec, for standard video frame rate of 30 fps.

Then, if object's motion in the video image is 1 mm between two segment frames, we have: v=1 mm/3.33×10⁻² sec=30 mm/sec=3 cm/sec. Assuming that such frames are sequentially numbered, as: 1, 2, 3, . . . n, . . . , a more general formula may be written, in the form:

Δt_{n,m}=(n−m)(Δt₀) (3-2)

where Δt₀=0.033 sec, and n,m, are even numbers. Assuming n=12, and m=9, n−m=3, and Δt_{12.9}=3(Δt₀)≈0.1 sec.

Similarly, embodiments of the invention may capture rotational KAPOs, with intermediate radius, r. Such KAPOs, for example, arrows of the clock, as shown in FIG. 8-2. In such a case, v=ωr, where ω is angular velocity, with ω=2πf, where f is frequency of rotation. Assume, for example, r=5 cm, and f=1 Hz; then ω=2πc/sec, and,

v=ωr=2πf×r=(2π/sec)(5 cm)=31.4 cm/sec (3-3)

Assuming a minute arrow, this KAPO rotates 5 sec between two sequent hour marks; then, we can adjust Δt₀=5 sec (i.e., 150-video frames), and between 12 p.m. and 5 p.m., we obtain: n−m=5. Then, using Eq. (3-1), we obtain Δt=25 sec, as expected.

Some displays have symbolic KAPOs that may be recognized as appearing and disappearing (thus, name: pseudo-digitization), as in the case of digits of digital clock. They can be recognized by standard character recognition algorithms, to be denoted as KAPO1, KAPO2, . . . , etc. In the case of digital clock and other digital meters, they come in the following sequences:

KAPO1,S,KAPO2,S,KAPO4,S,KAPO1, etc. (3-4)

where S is space symbol; these general sequences are not necessarily repeating. In general, such generalized KAPOs can be digits, letters, logos, etc. For example, if such KAPOs are digits, they can be denoted in the standard form: KAPO1=1, KAPO2=2, KAPO3=3, etc. Then, the sequence as in Eq. (8-4) has form: 1, 2, 4, 1, etc. In the case of such generalized KAPOs, the pseudo-digitization is synonymous with standard character recognition.

Some videos include a fourth class of KAPOs which is in gradual form, using graded scale of pixel's intensity, In such a case, embodiments of the invention locate these graded pixel scales and then clip them, using standard thresholding, as in FIG. 10C.

As illustrated in FIG. 10C, a “digital” profile 1011 of intensity curve in pixel scale 1010 is naturally squeezed 1013 to see regular video imagery 1015, as in 1017. Then, this natural intensity curve 1015 is clipped, using standard thresholding operation, with threshold intensity, I_{T} 1016 to result in a digitized 1019 image 1018 of the squeezed analog image 1015.

These two operations: squeezing and thresholding, create binary pattern of an analog image such as that of cloud, or other atmospheric phenomenon, as in standard avionics instruments. Such binary pattern is shown in FIG. 10D, where a plurality of shapes 1021 move on an analog display screen 1020.

In some embodiments, such binary contours are extracted, using novelty filtering, as shown in FIG. 10E, where crossed areas 1025 are novelty areas. The novelty areas are non-zero areas obtained from pixel extraction between two video frames, as shown in FIG. 10F.

All the above KAPOs and their digitization techniques can be applied in the case of vehicles with sophisticated cockpits, such as avionics platforms, military ground vehicles, and others. For sake of explanation, we consider avionics platforms CONOPS, including such platforms as helicopters, aircraft, etc. First, we should recognize four basic types of KAPOs, as discussed above, including:

Translational KAPOs (TRANS.)

Rotational KAPOs (ROT.)

Symbolic KAPOs (SYMB.)

Gradual KAPOs (GRAD.)

The translational KAPOs (TRANS.) are objects with translational kinematics, as in FIG. 10A. The rotational KAPOs (ROT.) are objects with rotational kinematics (FIG. 10B). The symbolic KAPOs are objects with cyclic kinematics as in the case of digital clock. The gradual KAPOs are those in gradual form, as in FIG. 10C. All flight instruments, and other instruments at avionics cockpit can be categorized within those four (4) types of KAPOs: TRANS., ROT., SYMB., and GRAD. For example, the basic six (6) flight instruments are: altimeter (feet), airspeed indicator (knots), turn and bank indicator (turn directions and coordination), vertical speed indicator (feet per minute), artificial horizon (attitude indicator), and directional gyro/heading indicator (degrees). There are different types of altimeter such as three-pointer altimeter, drum-type altimeter, and others. For purposes of further discussion, we should note cold weather altimeter errors, visualized in ICAO (International Civil Aviation Organization) Cold Temperature Error Table. In general, the flight instruments are organized into three groups: pilot-static instruments, compass systems, and gyroscopic instruments. Other instruments located at the cockpit include Engine Management Systems, such as CRM, and others. Of course, our interest is focused on kinematics of these avionics instruments and their visualization. Other sensors, reporting about flight, its history, platform health, are not located at the cockpit, but they are reported through ground station. Their kinematics is usually presented in mathematical form, as curves, for example, and belongs to GRAD. category. The categorization of flight instruments and engine sensors located at the cockpit is shown in Table 4.

TABLE 4
Categorization of Some Articulated Objects

| No. | Name | Function | Type |
|---|---|---|---|
| 1. | Altimeter | Shows Aircraft Altitude | ROT./SYMB. |
| 2. | Attitude Indicator | Shows Aircraft Attitude | GRAD./ROT. |
| 3. | Airspeed Indicator | Shows Aircraft Speed | ROT. |
| 4. | Magnetic Compass | Heading Relative to | GRAD./ROT./ |
| | | Magnetic North | TRANS. |
| 5. | Heading Indicator | Heading Relative to | GRAD./ROT. |
| | | Geographic North | |
| 6. | Turn Indicator | Direction/Rate of Turn | GRAD./ROT. |
| 7. | Vertical Speed | Climb/Descent Rate, | ROT./TRANS. |
| | Indicator | Air Pressure | |
| 8. | Course Deviation | Lateral Position in | ROT./TRANS./ |
| | Indicator | Relation to a Track | GRAD. |
| 9. | Radio Magnetic | Automatic Direction | ROT. |
| | Indicator | Finder-Related | |
| 10. | Automatic Dependant | ADS-B: Weather | GRAD. |
| | Surveillance-Broadcast | | |
| 11. | Traffic Avoidance | TCAS: Collision | GRAD. |
| | System | Avoidance | |
| 12. | Engine Management | Engine Health | ROT./TRANS./ |
| | System | | SYMB. |
| 13. | Aileron | Controls aircraft roll | ROT./TRANS |
| 14. | Landing gear | Supports aircraft on | ROT./TRANS |
| | | ground | |

According to Table 8-1, we can recognize all these avionics instruments as having various types of KAPOs. In all these cases we can recognize their function by pre-ATR, or manually, and, then, digitize them. For such operation it is sufficient to have good record of rather un-compressed video imagery by applying video recorder, for example, or even with direct observation.

By re-scaling novelty filtering operation in frame rate units, Δt₀, embodiments of the invention transfer analog video imagery of a given KAPO into mathematical data presented in the form of Characteristic Instrumental Digits (CIDs). As a result, these CIDS will represent measurement values as a function of time. Therefore, a given KAPO represents the measured quantity, such as attitude, h, as a function of time, t, in the form;

h=h(t) (8-4)

where h is an attitude of a given avionics platform, which such platform passes over time. For a given KAPO, visualized at the cockpit, in some embodiments its instrumental data may be obtained not only in the form of video imagery (or, visual observation), but also in the form of its measurement data presented in its equivalent mathematical (digital) form. Some embodiments obtain these mathematical data as back-up for its video imagery record and for determination if there are discrepancies between the data provided to the instrument and the instruments display.

In addition, some embodiments may receive information from direct measurement of systems, which is not displayed by an instrument or directly measurement by a sensor, but has an equivalent sensor. For example, a flight control surface or other articulated object may have a corresponding instrument displaying the surface's orientation using a calibrated sensor. However, if the calibration of the sensor is not accurate, than the instrument will not display a true representation of the control surface's orientation. In some embodiments, a video of the control surface (a KAPO) may be digitized to obtain information on the control surface's actual orientation. This information may be compared to the sensor data to determine if discrepancies between the two imply a miscalibration.

Embodiments of the invention store this mathematical data on the system CSMU. Further embodiments of the invention provide this to ground stations during wireless downloads or other data transfers.

As described above, many embodiments of the invention provide data to ground stations. In some embodiments, statistical analysis based on Bayesian Inference can be applied for failure prediction in avionics, space, and ground On-the-Move (OTM) vehicles, where the variety of measurement instruments are applied to report flight/motion performance and health of vehicles such as avionics platforms, including helicopters (rotary-wing aircraft) and aircraft (or, fixed-wing aircraft). Such instruments are located, usually, at cockpit, while some sensor data are directly reported at ground station. In any case, they are recorded by flight data recorders and other similar devices. In general, data recorders are used to record such measurement data. However, in general, it is very difficult to predict a failure event, or catastrophe of such avionics platform, because, there is multitude of more or less correlated measurement data given in analog or digital form, and those data are produced, through long periods of time (hours, days) of flight, or flights.

Nevertheless, there are some, rather discrete, anomalous events that can be extracted from those measurement data, which, properly selected and classified, can be used to effectively predict such catastrophic failure of avionics platform. These events are termed Bayesian-Anomalous Events, or BAEVENTS, to emphasize Bayesian Inference. The BAEVENTS can be represented in statistical form and it can be a set of such anomalous events that can be used to effectively predict a specific failure of a platform, which can be avionics one, space vehicle one, or ground vehicle one, manned, or unmanned.

All these catastrophic, or non-catastrophic failures, known to flight technicians, specialists, or experts, will be denoted in bold, as: A, B, C, . . . , N, where N is non-failure, while the related BAEVENTS will be donated in no bold, as: A, B, C, . . . , N, where A is dominant BAEVENT for a given failure A, or diagonal element, etc. There are also non-diagonal elements; for example, for failure A, B will be non-dominant, or non-diagonal element. In order to make Bayesian statistical analysis self-consistent, it is assumed that only one such BAEVENT occurs at a given time, which means, that they are relatively rare events. This assumption is without loss of generality because in the case of several such BAEVENTS happened at the same time, the next flight in the case of avionics platform must be halted any way.

In some embodiments, of the invention, anticipated failures we assign absolute probabilities a priori. Therefore, they are called priors, including: A, B, C, . . . , and non-failure N. They satisfy the following conservation relation which is given a priori, before any flight, in the form:

p(A)+p(B)+p(C)+ . . . +p(N)=1 (4-1)

Although it is difficult to predict failure based on a set of BAEVENTS, it is much easier to construct a direct history which describes what kind of BAEVENT or BAEVENTS can be created by a given failure. This inverse-in-time reconstruction of events can be created by following interviews with flight specialists, by study of professional flight literature, or other methods of data gathering. As a result of this, we can formulate direct conditional probabilities for each failure, say A, in the form:

p(A|A),p(B|A),p(C|A), . . . p(N|A) (4-2)

where the relevant conservation relation is also satisfied:

p(A|A)+p(B|A)+ . . . +p(N|A)=1 (4-3)

and the same relations for other failures: B, C, . . . , and non-failure, N, in the form:

p(A|N)+p(B|N)+ . . . +p(N|N)=1 (4-4)

Using Bayes Theorem, the well-known from Bayesian inference theory, we can obtain inverse (Bayesian) conditional probabilities, such as: p (A|A), p(A|B), p(A|N), etc. For simplicity, we can present them, only for limited case: A, B, N; i.e., for two failures: A, B, and non-failure, N, in the form:

$$p ( A \vert A ) = \frac{p ( A \vert A ) p ( A )}{p ( A \vert A ) p ( A ) + p ( A \vert B ) p ( B ) + p ( A \vert N ) p ( N )} \qquad ( 4 \text{-} 5 )$$

which can be transformed to the form:

$$p ( A \vert A ) = \frac{1}{1 + {q}_{BA} + {q}_{NA}} \qquad ( 4 \text{-} 6 )$$

where q are loss parameters in the form:

$${q}_{BA} = \frac{p ( A \vert B ) p ( B )}{p ( A \vert A ) p ( A )} ; {q}_{NA} = \frac{p ( A \vert N ) p ( N )}{p ( A \vert A ) p ( A )} \qquad ( 4 \text{-} 7 )$$

and, similar formulas for other diagonal Bayesian probabilities: p(B|B) and p(N|N), while the Bayesian non-diagonal element has the form:

$$\begin{matrix}p ( A \vert B ) = \frac{p ( B \vert A ) p ( A )}{p ( B \vert A ) p ( A ) + p ( B \vert B ) p ( B ) + p ( B \vert N ) p ( N )} & ( 4 \text{-} 8 ) \\ p ( A \vert B ) = \frac{1}{1 + {q}_{BB} + {q}_{NB}} & ( 4 \text{-} 9 )\end{matrix}$$

In the above formulas, p(A), p(B), . . . are so-called a priori absolute probabilities, or priors, while p(B|A) is direct conditional probability that B-BAEVENT has been observed, assuming that A-failure did occur. Also, the inverse (Bayesian) probability, p(A|C) is probability that A-failure is predicted, assuming that C-BAEVENT did occur.

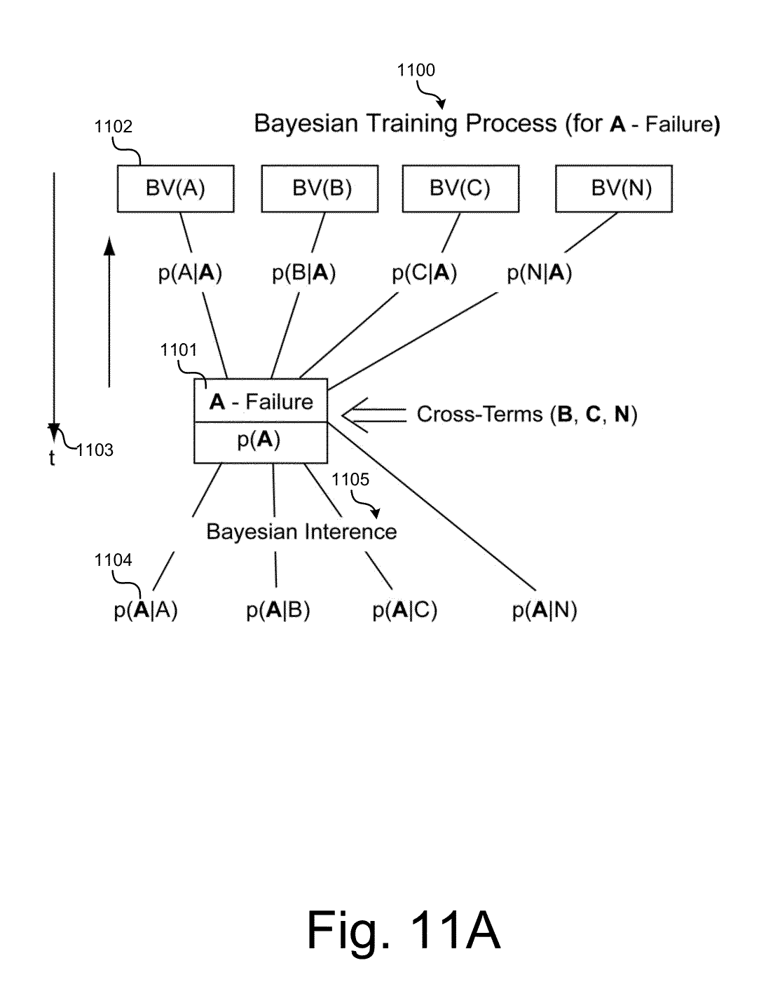

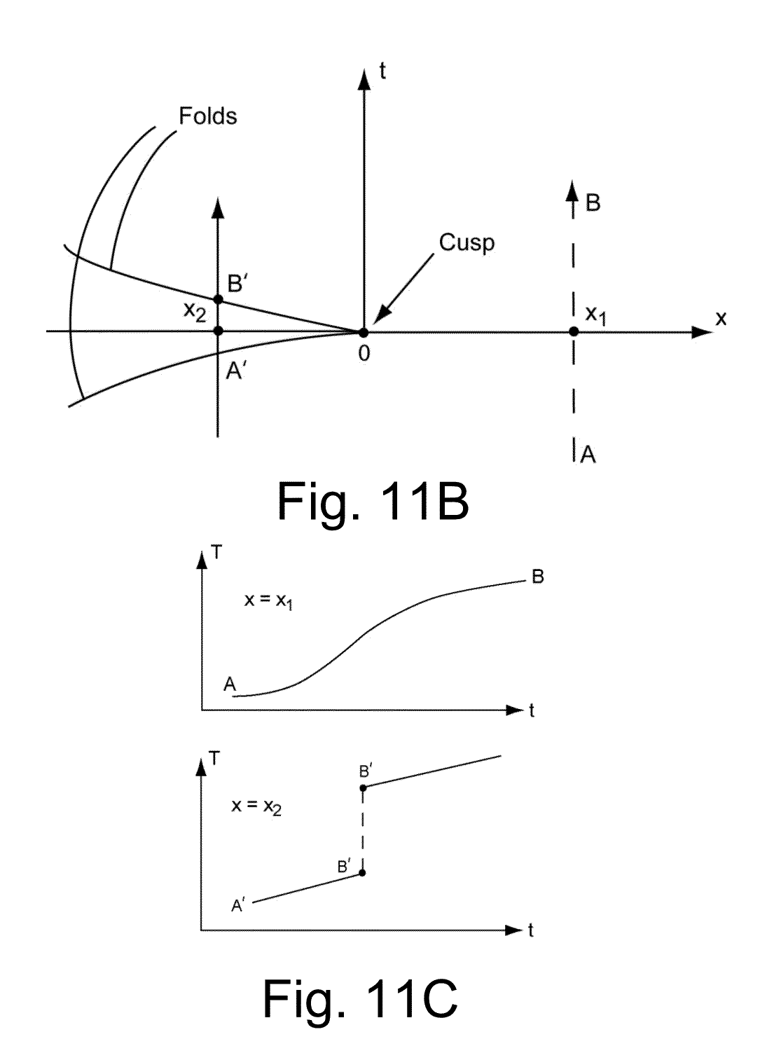

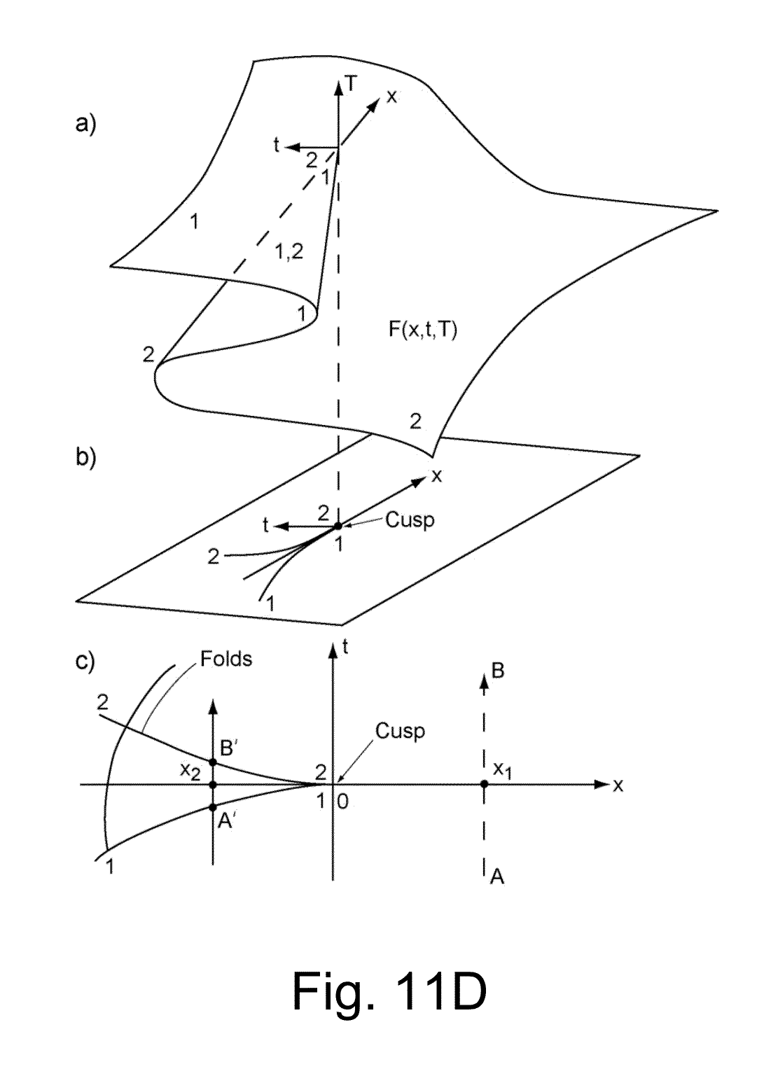

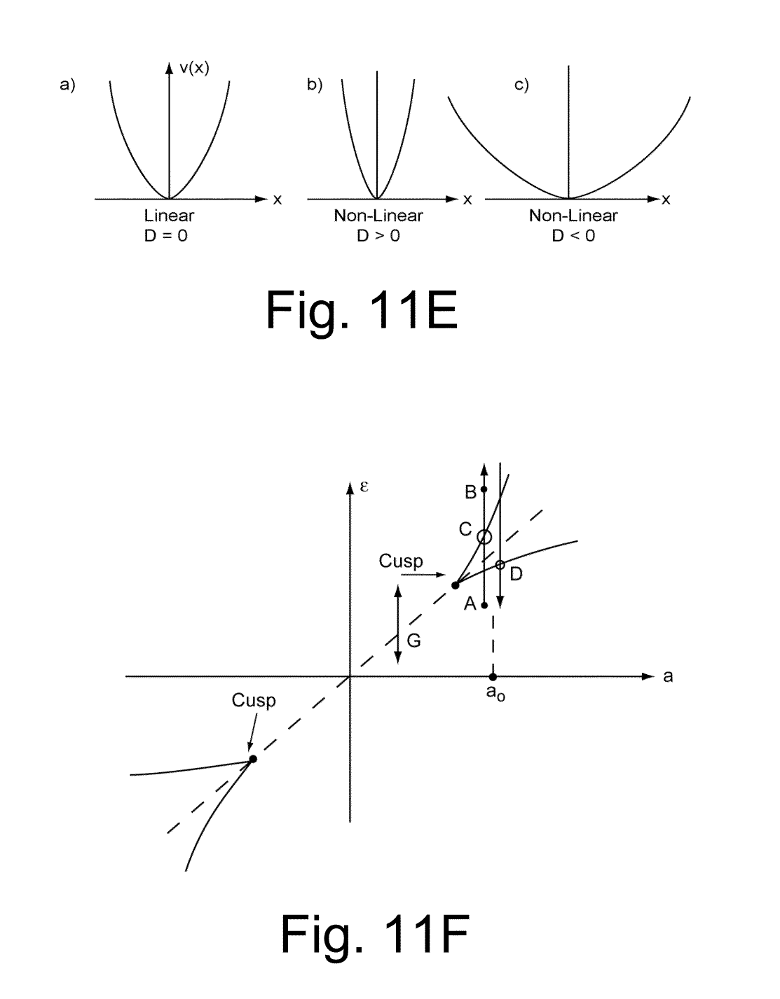

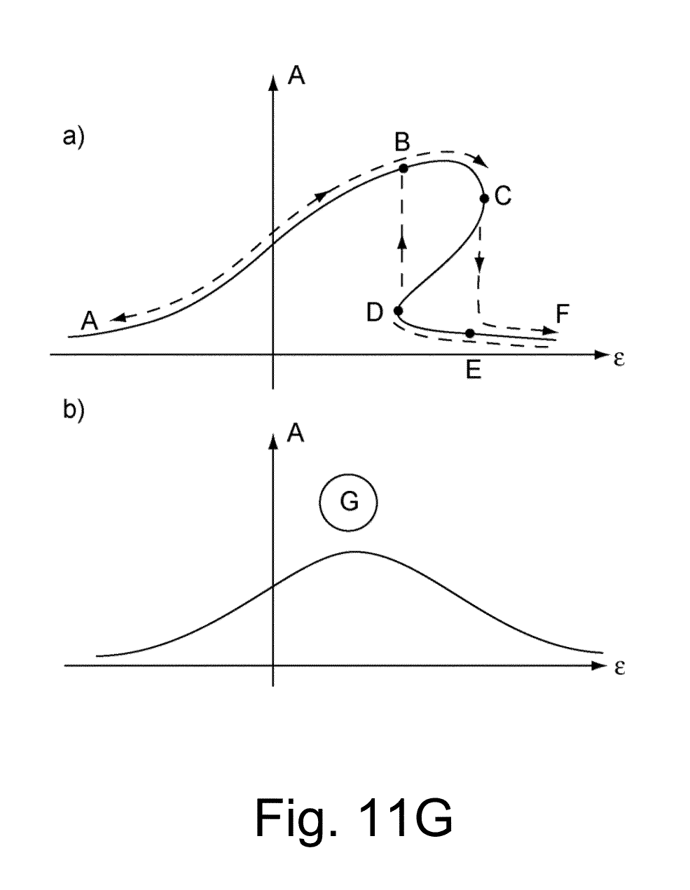

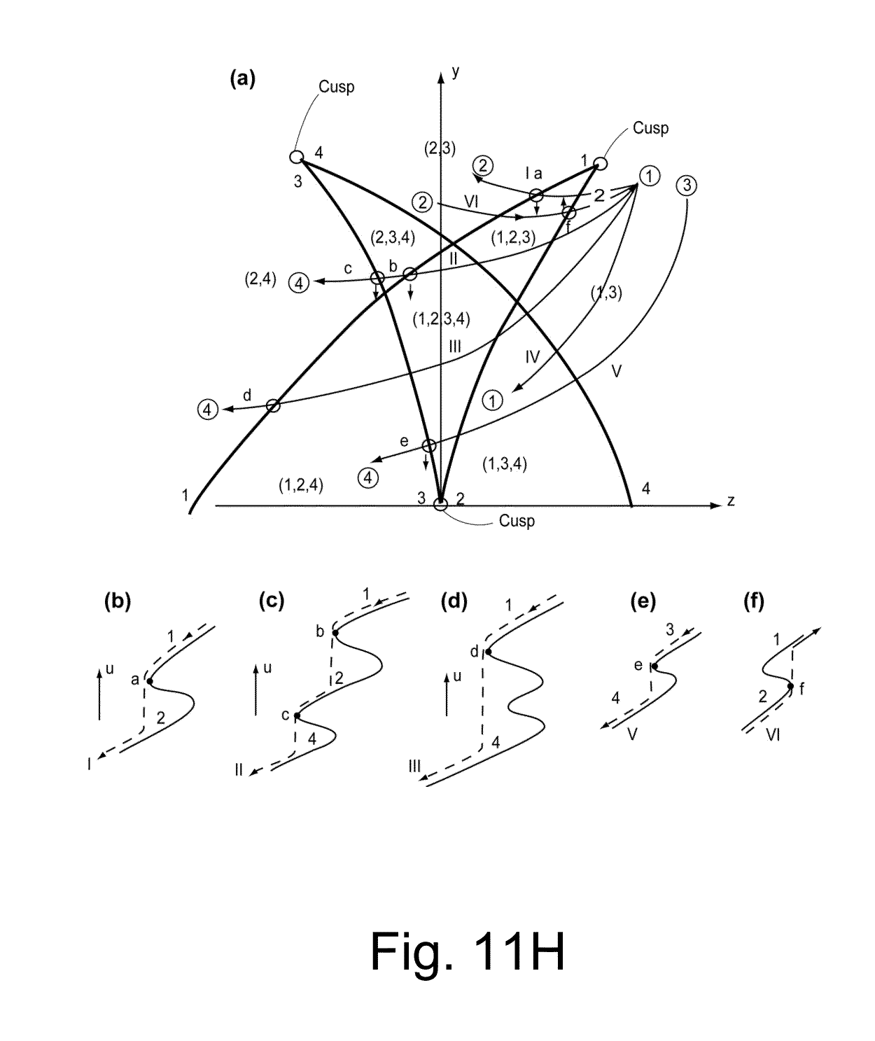

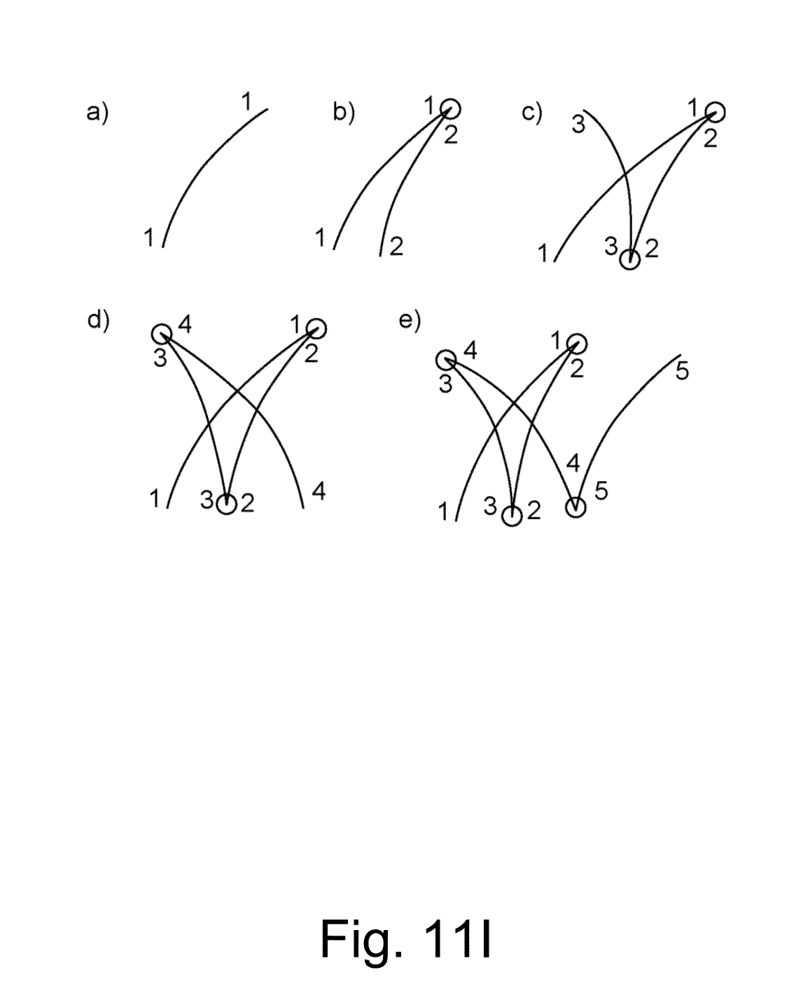

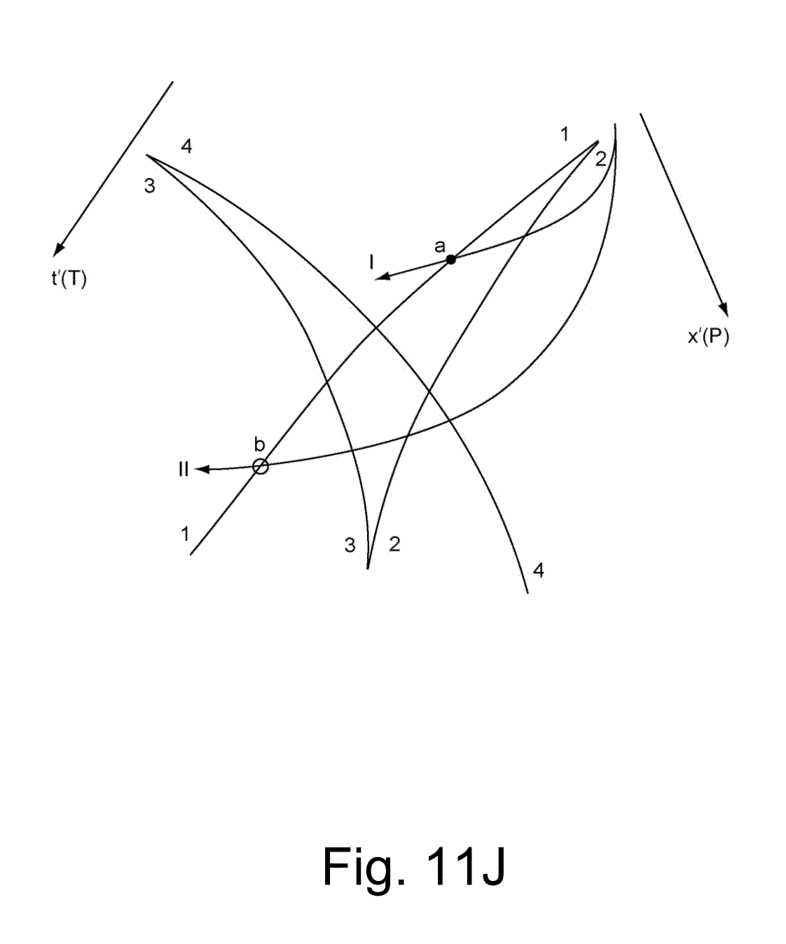

FIG. 11A illustrates a block schematic of Bayesian failure-prediction process implemented in accordance with an embodiment of the invention. This embodiment illustrates a Bayesian training process 1100 and resulting reading process by Bayesian inference 1105. The Bayesian training process is provided using inverse-in-time rule, by applying three BAEVENTS 1102: BV(A), BV(B), and BV(C), and A-failure 1101, with absolute probability, p(A). Cross-terms including other failures: B, C, N, are also included.

Following this procedure, basic matrices may be constructed: \hat{M}^{(d)}-direct, and \hat{M}^{(B)}-Bayesian, representing direct conditional probabilities and inverse (Bayesian) conditional probabilities, respectively, in the form:

$$\begin{matrix}{\hat{M}}^{( d )} = [ \begin{matrix}p ( A \vert A ) & p ( B \vert A ) & p ( N \vert A ) \\ p ( A \vert B ) & p ( B \vert B ) & p ( N \vert B ) \\ p ( A \vert N ) & p ( B \vert N ) & p ( N \vert N )\end{matrix} ] & ( 4 \text{-} 10 ) \\ {\hat{M}}^{( B )} = [ \begin{matrix}p ( A \vert A ) & p ( B \vert A ) & p ( N \vert A ) \\ p ( A \vert B ) & p ( B \vert B ) & p ( N \vert B ) \\ p ( A \vert N ) & p ( B \vert N ) & p ( N \vert N )\end{matrix} ] & ( 4 \text{-} 11 )\end{matrix}$$

These matrices have identical form except bolds here have been shifted. Also, in both cases, diagonal elements describe the failure event, while non-diagonal elements provide the probabilities that the measurements lead to other types of failure events. In ideal case, the matrix (4-10) is fully diagonal. Then, due to conservation relations, we have:

$${\hat{M}}^{( d )} = [ \begin{matrix}1 & 0 & 0 \\ 0 & 1 & 0 \\ 0 & 0 & 1\end{matrix} ] \qquad ( 4 \text{-} 12 )$$

i.e., this matrix is unity matrix. Then, also \hat{M}^{(B)} is the unity matrix. In both cases, the matrix row values should be added to 1. The direct matrix elements can be named as follows: p(A|A), p(B|B) are probabilities of failure detection, while p(N|N) is probability of failure miss. Also p(A|N) and p(B|N) are false positives, while p(N|A), p(N|B) are false negatives. Also, p(A|B), p(B|C), etc., can be called cross-failures. The Bayesian elements: p(A|A) and p(B|B) can be called positive predictive values by medical analogy. It should be observed that, because of the conservation relations, the convention used in Eqs. (4-10) and (4-11) is shifted in respect to columns and rows.

As an example, embodiment consider the following avionics CONOPS example. After interviews and studies a list of highly-possible failures for specific avionics platform (e.g., helicopter) is defined, both catastrophic and non-catastrophic. This list is denoted as: A, B, C, D, . . . , N, and normalized 1, using Eq. (4-1). Each failure, say B, has been studied in detail, and a list of probable three BAEVENTS: A, B, D, has been identified, including N, and normalized, according to Eqs. (4-3) and (4-4). Then, direct matrix (4-10) has been formulated. Then, Bayesian formulas such as: (4-5) through (4-9) have been calculated. Then, Bayesian matrix (4-11) has been formulated. The advantage of this Bayesian approach can be seen by observing how far direct matrix (4-10) is departed from its ideal diagonal form (4-12). If this departure is small it means that one probability of success with this method is high. Otherwise, it will be proportionally lower. In some embodiments, a software algorithm is used for BAEVENTS finding.

In these embodiments, both flight instruments and Engine Health (selected) instruments are presented in the form of pilot-friendly GUI (Graphic User Interface) at the cockpit, and digitized. Therefore, it is relatively easy to find BAEVENTS in this case.

In these embodiments, results are presented in less user-friendly mathematical form; i.e., mostly in the form of mathematical curves (graphs). Nevertheless, also in this case, we can develop relevant API to identify BAEVENTS in discrete forms, for example using KAPOS digitization as described with respect to FIG. 10.

In particular embodiments, the identification of which data are sufficient for the discovery of BAEVENTS utilizes catastrophe theory. This is mathematical theory of manifolds, formulated by Whitney (U.S. 1955), Thom (France), Arnold (Russia), and others. Here, for sake of explanation, we consider only 3D space (x, y, z), where (x, y) are (external) so-called control-variables, while z-coordinate is (single) (internal) state variable. Generalizations to higher dimensional spaces are straightforward. In such a case, the so-called co-rank of catastrophe is 1, since there is only single state variable, and we have the following elementary catastrophes: fold, cusp, swallowtail, butterfly, wigwam, and higher ones; with singularities: z², z³, z⁴, z⁵, z⁶, and z⁷, respectively. (Singularity is the highest polynomial degree of so-called hyper-surface, or manifold.) Also, the number of cusps in so-called bifurcation curves is: 0, 1, 2, 3, 4, 5, 6, respectively, while co-dimension, or number of control variables is 1 for fold (2D-space), 2 for cusp (3D-space), 3 for swallowtail (4D-space; i.e., one state variable and three control variables: x, y, t), etc. This is shown in Table 5.

Even in the case of analog (continuous) curves, or surfaces that are used for ground station GUIs, embodiments may use a discrete set of mathematical objects (or, catastrophes) that can be used for identification of BAEVENTS. Consider cusp catastrophe, for example. Assume, that a state variable, z, is temperature, T, while two control variables are space coordinate, x, and time coordinate, t. The cusp is first non-trivial stable catastrophe, defined by the 2D-surface (so-called equilibrium surface):

F(x,y,z)=4z³+2xz+y=0 (4-13)

with condition for partial differential:

$$\frac{\partial F}{\partial z} = G ( x , y , z ) = 12 {z}^{2} + 2 x = 0 \qquad ( 4 \text{-} 14 )$$

for fold catastrophes. By substituting Eq. (4-14) into Eq. (4-13), we obtain so-called bifurcation curve defining position of folds as (x, y)-projection:

$$\frac{{x}^{3}}{27} + \frac{{y}^{2}}{8} = 0 \qquad ( 4 \text{-} 15 )$$

TABLE 5
Co-Rank 1 Catastrophes

| Name of | Co- | Co- | Number of | Number of | |
|---|---|---|---|---|---|
| Catastrophe | Rank | Dimension | Folds | Cusps | Singularity |
| Fold | 1 | 1 | 1 | 0 | z³ |
| Cusp | 1 | 2 | 2 | 1 | z⁴ |
| Swallowtail | 1 | 3 | 3 | 2 | z⁵ |
| Butterfly | 1 | 4 | 4 | 3 | z⁶ |
| Wigwam | 1 | 5 | 5 | 4 | z⁷ |
| Higher | 1 | 6 | 6 | 5 | z⁸ |

For example, assume that some 1D-element of engine, say, piston, can have various positions, denoted by x-coordinate. From characteristic cusp (or Riemann-Hugoniot) catastrophe shape (cusp point catastrophe is at x=y=z=0), we obtain that, if x-coordinate is at the right side of the cusp location; then the state-coordinate temperature, T, for example, changes smoothly as a function of time, t, while for other x₂-position at the left of cusp location, the temperature jumps at point B′, a kind of catastrophe. In order to formulate these facts mathematically, we are making the following coordinate transformation:

x→x,y→−t,z→T (4-16)

Then, the equilibrium surface (4-13) becomes

F(t,x,T)=4T³+2xT−t=0 (4-17)

and, the singularity set (4-14) becomes:

$$\frac{\partial F}{\partial T} = G ( t , z , T ) = 6 {T}^{2} + x = 0 \qquad ( 4 \text{-} 18 )$$

Thus, the cusp location is at t=0, and T=0, or:

(t,x,T)=(0,0,0) (4-19)

and the bifurcation curve (4-15) has the form:

$$\frac{{x}^{3}}{27} + \frac{{t}^{2}}{8} = 0 \qquad ( 4 \text{-} 20 )$$

which is shown in FIG. 11B, where the smooth T(t)-curve is denoted by broken line, while catastrophic T(t)-curve is denoted by continuous line. FIG. 11B illustrates cusp Bifurcation Curves in (t, x)—control variables, where x—is spatial coordinate, while t is time coordinate. At x₁-position, (broken line, A-B), temperature changes smoothly as a function of time, t; while at x₂-position, (a continuous line A′-B″) temperature jumps at point B′, creating catastrophic temperature jump. Those curves are shown in FIG. 11C. FIG. 11C illustrates of two curves T(t) from FIG. 11B, for (a) x=x₁, and (b) x=x₂. In B′-point we have catastrophic jump.

From this example it is clear, that, in spite of continuous equilibrium surface we have jumps in T(t)-functions, depends on x-coordinate location. The other examples of catastrophes will be caustics in optics, or non-linear oscillations, described by Van der Pol equation, for example. Embodiments of the invention determine where these jumps occur, allowing the prediction of discrete events from minor changes in various data measurements.

In additional embodiments, the equilibrium 3D surface (t, x, T), can be replaced by 4D equilibrium surface (t, x, y, T). Then, catastrophic T-jumps can be observed at some points (x, y); same, with 5D equilibrium surface (t, x, y, z, T), where such catastrophic T-jumps can be found at volume (x, y, z). Therefore, these generalizations can be referred to higher catastrophes as in Table 5. Also, one state variable, T, can be generalized to two, or more state variables. In all these cases, the principle is the same: in spite of smooth equilibrium surfaces, we can identify discrete set of anomalies, called catastrophes. Moreover, these discretization principles can be extended to phenomena which can be described such precisely in mathematical formulas as theory of catastrophes.

All these cases are shown to emphasize a method of generating of discrete anomalous events in spite the fact that the general mathematical structure of manifolds guiding related physical processes can be continuous. Moreover, such anomalous events, or BAEVENTS, can be found automatically, without intervention of experts. In addition, the catastrophes can be predicted even in the case when dominant events (such as A for A) do not exist. Then, we can still formulate matrices as in Eqs. (4-10) and (4-11).

As other specific example of catastrophic BAEVENT, we consider a mathematical catastrophe of rank 2; i.e., with two state variables. Assume that these state variables are pressure, p, and temperature, T. We assume one (x), two (x, y), or three (x, y, z) control variables that can be only space, or space and time. It is known from the physics of an engine that if, for specific control variable, the pressure will jump; then, we need to add a shot of fuel. Otherwise, it will be an engine failure, catastrophic, or non-catastrophic one.

In general, the search process of BAEVENTS can follow this example for a set of specific failures which, at the 1st step, can be found in literature, by interview with experts, experiment, or other data gathering methods. However, in the next step, when the set of failures is sufficiently dense, we can produce broader fuzzy sets of failures, including also ones that are not included in the 1^{st} step BAEVENT set, using a kind of Bayesian neural network.

This process of searching failures or BAEVENTS can be classified as data mining. In this example embodiment, the qualitative methods of catastrophe extraction are applied, using Cusp and Butterfly catastrophes as examples. This is important approach for practical reasons because it is an introduction to automatic or autonomous mode, that can be done by relevant algorithmic software algorithm.

As an example, a very broad class of non-linear oscillators leads to cusp singularities. This is an important demonstration of the analysis methods of certain embodiments because only a slight change of oscillator energy potential profile (this potential is different than the catastrophic potential) can lead to cusp catastrophes. The second example is using Butterfly catastrophe and it is using direction-convention, for the first time discussed in this patent, to the best of our knowledge. This direction-convention (DC) allows to determination catastrophic jumps based on purely qualitative (geometrical) discussion, simplifying the programming necessary to implement some embodiments.

FIG. 11D illustrates a cusp bifurcation set, as in FIG. 10B. This figure also includes an equilibrium surface F(x,t,T), as in FIG. 11D(a), and its (x,t) folds projection (FIG. 11D(b)), as well as the equilibrium set (FIG. 11D(c)). Accordingly, this figure illustrates Cusp Catastrophe in 3D space (x,t,T), where T (temperature) is state variable, while x-spatial coordinate, and t-time are control variables, including: (a) Equilibrium manifold surface, which is z³-polynomial, with two folds and point cusp at (0,0,0); (b) Fold (x,t)-projection with two folds: 1-1 and 2-2; (c) Bifurcation set in (x,t)-control variable, similar to FIG. 11B.

The geometrical interpretation is a kind of qualitative one, where, for Direction Convention (DC) purposes we need to determine which fold is higher. In order to determine this, we need to analyze singularity set (10-18) and equilibrium surface (10-17), by eliminating x-coordinate from these equation, in the form:

4T³+2xT−t=0 (5-1)

and,

6T²+x=0 (5-2)

thus,

$$x = - 6 {T}^{2} ⇒ {T}^{3} = - \frac{t}{8} . \qquad ( 5 \text{-} 3 ab )$$

According to Eq. (5-3b), for t<0, we have T>0; while for t>0, we have T<0. Thus, 1-1 fold in FIG. 5-1(c) has higher value (T>0) then 2-2 fold (T<0). (This explains notation (1-1) and (2-2) for folds.) Therefore, at B′, we have, indeed, the temperature jump, rather than its drop. In various embodiments, the direction convention may be established according the failure type to be predicted. Of course, this reasoning can be repeated for any generalized coordinates (x,y,z).

As an example, this is applied to the non-linear oscillator. The non-linear oscillator is important physical example in mechanics and electromagnetism. Its differential equation has the following general form:

\ddot{x}+k\dot{x}=F cos γt+Fₓ(x) (5-4)

where: x(t) is deflection coordinate, around equilibrium at x=0; \dot{x}=dx/dt, \ddot{x}=d²x/dt²; F cos γt is stimulation force term, with F—force normalized amplitude and γ—stimulating frequency which is close to resonant frequency of linear oscillator, ωₒ, in the form:

γ=ωₒ(1+ε); ε≦1 (5-5)

where ε is small value, and Fₓ(x) is general oscillator force that can be expanded in Taylor series around x=0, in the form:

Fₓ(x)=−ωₒ²x−bx²−ax³−cx⁴−dx⁵− (5-6)

where, a, b, c, d are constants that can be negative.

For purpose of finding relation between amplitude of stable vibration, A, and γ-stimulated frequency (so-called dispersion relation), we are searching a particular solution, in the form including phase, (I), shift:

x=A cos(γt−φ). (5-7)

It is important to observe that parity terms: bx², cx⁴, etc., introduce only constant addition and harmonics. The constant addition changes stability, however, while harmonics are not of interest to us, since, for catastrophe purposes, embodiments consider only vibration deviations close to fundamental frequency, y; thus, we cancel them: b=c=0; thus, the only interested are non-parity terms:

Fₓ(x)=ω_{o x}²−ax³−dx⁵− (5-8)

These terms also introduce harmonics which are rejected as above, although they also contribute to the fundamental frequency. For example, according to the well-known trigonometric identity: cos³ α=(¼)cos 3α+(¾)cos α, we have the addition with extra factor: (¾), in the form:

x³=(3/4)A³ cos(γt−φ) (5-9)

and similar relations to higher terms such as: dx⁵. In general, those additions modify the profile of the linear oscillator potential function:

$$V ( x ) = \frac{{Bx}^{2}}{2} ⇒ V ( x ) = \frac{{Bx}^{2}}{2} + \frac{{Dx}^{4}}{4} \qquad ( 5 \text{-} 10 ab )$$

where B>0, D₂₂ ²¹ 0, which is illustrated in 11E. FIG. 11E illustrates various shapes of oscillator potential, V(x), including: (a) D=0; (b) D>0; (c) D<0.

In those cases: the harmonic force, is

$${F}_{x} = \frac{\partial V}{\partial x} \qquad ( 5 \text{-} 11 )$$

and all three potential functions are symmetrical. Therefore, for further analysis, without loss of generality, we can also put: d=0; then,

Fₓ(x)=−ωₒ²x−ax³ (5-12)

and, differential equation has the form:

\ddot{x}+k\dot{x}+ωₒ²x+ax³=F cos γt. (5-13)

By substituting Eq. (5-7) into Eq. (13), we obtain:

−γ²A cos(γt−φ)−γkA sin(γt−φ)+Aωₒ² cos(γt−φ)+(3/4)aA³ cos(γt−φ)=F cos γt. (5-14)

Since, we have two unknowns: A, and φ, we require that terms with cos γt and sin γt should be independently equal to zero; and using trigonometric identities (such as: cos(α+β)=cos α cos β−sin α sin β, and: sin(α+β)=sin α cos β+sin β cos α), we obtain, the following equation for sin γt-terms:

$$( A {ω}_{o}^{2} - A {γ}^{2} + \frac{3 a {A}^{3}}{4} ) sin φ = γ k A cos φ \qquad ( 5 \text{-} 15 )$$

yielding the 1^{st} unknown, phase:

$$tan φ = \frac{γ k}{( {ω}_{o}^{2} - {γ}^{2} ) + \frac{3 a {A}^{2}}{4}} . \qquad ( 5 \text{-} 16 )$$

From Eq. (5-5), we obtain, for ε<<1:

γ²≈ωₒ²(1+2ε); ωₒ²−γ²=2ωₒ²ε (5-17ab)

and, Eq. (5-16) reduced to:

$$tan φ = \frac{γ k}{\frac{3 a {A}^{2}}{4} - 2 {ɛω}_{o}^{2}} \qquad ( 5 \text{-} 18 )$$

which agrees with the literature; however, it should be noted that preliminary analysis of this section makes this result much more general in a qualitative sense than so-called Duffing Eq. (5-12), since, we discuss more general case: (5-6), than (5-12).

In order to find the second unknown, A, we need to apply identity: cos⁻² φ=1+tan² φ, and find also cos φ from Eq. (5-18). Then, finally, we obtain the following equation for amplitude, A, as a function of γ:

$$A = \frac{F}{\sqrt{{( {ω}_{o}^{2} - {γ}^{2} + \frac{3 a {A}^{2}}{4} )}^{2} + {γ}^{2} {k}^{2}}} . \qquad ( 5 \text{-} 19 )$$

For a=0, we obtain the well-known result for linear oscillator. In order to obtain agreement with literature, we need to place ωₒ=1, which is non-physical assumption, only good for mathematical analysis. Then, we realize, that Eq. (5-19) can be presented in the form:

$${{A}^{2} ( \frac{3 a {A}^{2}}{4} - 2 ɛ )}^{2} = {F}^{2} - {k}^{2} {A}^{2} \qquad ( 5 \text{-} 20 )$$

which is cubic in respect to A²; then, we can expect cusp catastrophes. By substituting state variable: u=A², with two control variables: ε and a, we obtain the equilibrium surface in the form:

$$G ( u ) = {u ( \frac{3 a u}{4} - 2 ɛ )}^{2} + {k}^{2} u - {F}^{2} = 0 \qquad ( 5 \text{-} 21 )$$

and singularity set, in the form:

$$\frac{\partial G}{\partial u} = \frac{27}{16} {a}^{2} {u}^{2} - 6 a ɛ u + ( 4 {ɛ}^{2} + {k}^{2} ) = 0 \qquad ( 5 \text{-} 22 )$$

Therefore, the cusp catastrophe location is determined by the following equation:

$$\frac{{\partial }^{2} G}{\partial {u}^{2}} = \frac{27}{8} {a}^{2} u - 6 a ɛ = 0 ⇒ u = \frac{16 ɛ}{9 a} . \qquad ( 5 \text{-} 23 ab )$$

By eliminating u-variable, we obtain two cusps, in the form:

(a,ε)=±(32k³\sqrt{3}/27F²,k\sqrt{3}/2). (5-24)

The bifurcation set is shown in FIG. 11F.

Similar cases have been analyzed by Landau, without using catastrophe theory; please, see: L. Landau, E. Lifszitz, Mechanics, Moscow, 1958. Following his reasoning, we can re-draw cases in FIG. 11F as in FIG. 11G.

According to FIG. 5-4(a), the path ABCEF presents a sudden drop of amplitude, A, as a function of stimulated frequency, y, characterized by difference from linear resonant frequency, ωₒ, as in Eq. (5-5). This is physical case, because, according to FIG. 5-3, the non-linearity coefficient, a, is constant: a=aₒ. On the other hand, for the path: FEDBA we have sudden jump of amplitude A. In contrast, outside of catastrophe region, as in path G, we do not have any catastrophes, as in FIG. 5-4(b). In general, we see, that, in the region close to linear case (|ε|, |a|, ^{˜}0), we do not have anomalous events (catastrophes). We see, that, according to general comments at the beginning of this section, this is a general conclusion, related to cases close to fundamental frequency (ε<<1).

We see, that, for very general non-linear oscillator cases (that cover: mechanical vibration and electrical resonance circuits with lumped constants), we can expect catastrophes away from linear regions in such a sense that both control variables: a and ε are quite different from zero (demonstrated by diagonal location of bifurcation sets in FIG. 5-3), but still close to linear case (ε<<1) in a sense of Eq. (5-5). Practically, it means that, since, according to Eq. (5-17(b); we obtain:

$${ω}_{o}^{2} - {γ}^{2} = 2 {ω}_{o}^{2} ɛ ⇒ Δ γ = \vert γ - {ω}_{o} \vert = {ω}_{o} ɛ ⇒ \frac{Δ γ}{{ω}_{o}} = ɛ \qquad ( 5 \text{-} 25 abc ) )$$

therefore, the γ-frequency relative deviation from fundamental frequency, ωₒ. equal to ε, should be small (ε<<1); i.e., less than 1%, for example; i.e., when fundamental frequency is 10 kHz, its deviation should be less than 100 Hz. This is important conclusion, because, such small deviations can happen quite often; thus, non-linearities (|a|>0) with such small deviations are prone to catastrophes. The basic criterion where we can find cusp catastrophes is Eq. (5-24) which determines their locations by comparing with values of control variables (a, ε). For example, for control variable, a, the increasing of stimulated (normalized) force amplitude, F, (related to non-normalized force amplitude, f, divided by oscillator mass, m: F=f/m), should be compensated by increasing dumping constant, k, according to relation: |a|=32k²\sqrt{3}/27F². Otherwise, the cusp location can be very close to linear case.

As an another example of an catastrophe analysis in accordance with an embodiment of the invention, a Butterfly Catastrophe is presented. The Butterfly Catastrophe is more complicated than that for Cusp Catastrophes, because, in such a case, we have four (4) control variables, denoted by: x,y,z,t (t—does not need to be time), while this corank-1 catastrophe has still only one state variable, denoted by u; thus, we have 5D case. To show general formalism of such catastrophe, we start from catastrophe potential, V, with u⁶-singularity; then, with equilibrium surface, F, and singular set, G; then, with cusp location set, H; then, with swallowtail catastrophes set, I; and finally, the butterfly location set, J, in the form:

$$\begin{matrix}V = {u}^{6} + t {u}^{4} + x {u}^{3} + y {u}^{2} + z u = 0 & ( 5 \text{-} 26 a ) \\ F = \frac{\partial v}{\partial u} = 6 {u}^{5} + 4 t {u}^{3} + 3 x {u}^{2} + 2 y u + z = 0 & ( 5 \text{-} 26 b ) \\ G = \frac{\partial F}{\partial u} = 30 {u}^{4} + 12 t {u}^{2} + 6 x u + 2 y = 0 ; FOLDS & ( 5 \text{-} 26 c ) \\ H = \frac{\partial G}{\partial u} = 120 {u}^{3} + 24 t u + 6 x = 0 ; CUSPS & ( 5 \text{-} 26 d ) \\ I = \frac{\partial H}{\partial u} = 360 {u}^{2} + 24 t = 0 ; SWALLOWTAILS & ( 5 \text{-} 26 e ) \\ J = \frac{\partial I}{\partial u} = u = 0 ; BUTTERFLY . & ( 5 \text{-} 26 f )\end{matrix}$$

In general, the bifurcation set is 4D-hypersurface; so, it is impossible to draw. However, we can analyze its cross-sections; such, as for:

x=0, t=−1 (5-27)

for example; then,

F=6u⁵−4u³+2yu+z=0 (5-28)

also, from Eq. (5-26c), we have: y=−15u⁴+6u²; then, F=24u⁵+8u³+z=0, or: z=24u⁵−8u³.

Now, for cusp, and x=0, t=−1, we have: H=120u³−24u=0; thus, 5u²=1, or u=±0.45. Therefore, we have two symmetrical cusps, with: u₁=0.45, and u₂=−0.45; then z₁=−0.2585, and z₂=0.2585. Therefore, for u>0, z<0; and, for u <0, z>0, which is illustrated in FIG. 11H, where fold (4-4) has much lower state variable value (u<0), then fold (1-1). In this figure, we have also the 3^{rd} cusp, at the center; so, we denoted them as: (2-3)—at the center, (3-4)—at the left, and (1-2)—at the right. Six (6) paths, or control trajectories, or evolution curves, are shown, denoted by: I, II, III, IV, V, and VI. Our goal is to find all u-amplitude jumps without using mathematics; thus, provide a “natural” geometric way to identify anomalous events (BAEVENTS), as shown in FIG. 11H, for the bifurcation cross-section (y,z), for a given: x=0, t=−1, as in Eq. (5-27). Using Direction-Convention (DC), as before, we have obtained that the highest fold is denoted by (1-1); then: (2-2), (3-3), and (4-4). By using FIG. 5-1(a) as a basic reference, we see that both surface sheets 1 and 2 coincide at the cross-area between folds: (1-1) and (2-2); while at the left of lower fold (2-2), we have only higher sheet 1, and at the right of higher fold (1-1), we have only lower sheet 2. Generalizing this methodology, we identify sheet location in FIG. 11H, using brackets such as: (2,4), (2,3,4), etc. We see that in the central area, we have all four sheets: (1,2,3,4), while far left, we have only two sheets: (2,4), and at the far right: (1,3). Also, at the top, we have: (2,3), and at the left bottom; we have three sheets (1,2,4), and at the right bottom: (1,3,4). Therefore, at starting point (1), we assume that 4 control trajectories: I, II, III, and IV, start from sheet—1, while one trajectory (V) starts from sheet—3. Also, one trajectory (VI) starts from sheet—2. Now, using DC of FIG. 5-1, we conclude that I-trajectory has a drop (or catastrophic tangential points) at a-point, into sheet—2, as also shown in FIG. 5-5(b). The next II-trajectory has two drops: at b-point into sheet—2, and at c-point into sheet—4, as also shown in FIG. 5-5(c). The next III-trajectory has only one big drop, at d-point, into sheet—4, at once, as shown in FIG. 5-5(d). On the other hand, IV-trajectory does not have any catastrophes. Also, V-trajectory that starts from sheet—3, has only one drop, into sheet—4. Finally, VI-trajectory, starting from sheet—2, has (positive) jump at f-point, into sheet—1, as shown in FIG. 5-5(f).

In a similar way, we can analyze other corank-1 catastrophes, as shown in FIG. 11I. This figure illustrates Cusp-Fold Topology for Bifurcation Cross-Sections, including: (a) fold; (b) cusp; (c) swallowtail; (d) butterfly; (e) wigwam. Folds are denoted by: (1-1), (2-2), (3-3), etc., while cusps by “0”, as: (1-2), (2-3), 3-4), etc.

FIG. 11J illustrates a catastrophe analysis applied to temperature and power supply data, in accordance with an embodiment of the invention. In this example, we can use time variable (t′) and space variable (x′); then, for specific configuration we can obtain either small drop (small catastrophe), or big catastrophe, as in I and II-control trajectories, respectively. More interesting is the 2^{nd} case, where instead of (t′, x′), we have two physical control variables (T, P), where T—planning time and P—project cost. In this 2^{nd} case, the state variable is processing power, G, for example. Then, for I-trajectory, the planning time, T, is increasing (which is the risky effect), but project cost, P, is only moderately increasing. As a result we escape the big catastrophe, only minor project cost (G) drop at a-point, from sheet 1-1 to sheet 2-2. However, if project cost increases with a constant increase in planning time, there is a risk of a large drop at b-point, for II-control trajectory.

The latter case is characteristic for general system optimization strategy which shows that the variation of two control parameters (T, P), if it is done moderately, it can cause only minor catastrophe; otherwise, the major catastrophe can occur. FIG. 11J shows that higher-level catastrophes with complex manifold equilibrium surface topologies are needed to show more complex strategies.

As another example, assume that t′-variable is planning time but x′-variable is cost, and state variable is risk avoidance. In this case, 1-trajectory shows that long-planning (t′-increasing) is only not bad if, as a result, the program cost can decrease. Then, risk avoidance can drop only slightly (so, risk will increase moderately). Otherwise, if both planning time and cost will significantly increase; then, we can face very high risk increasing, as in the case of II-trajectory. The general conclusion from analyzing Butterfly catastrophe is such that, if we act moderately, as in the case of I-trajectory, we can face some minor catastrophe, but this could be a good warning against bigger catastrophe. Otherwise, without warning we can face a big catastrophe, as in the case of II-trajectory.

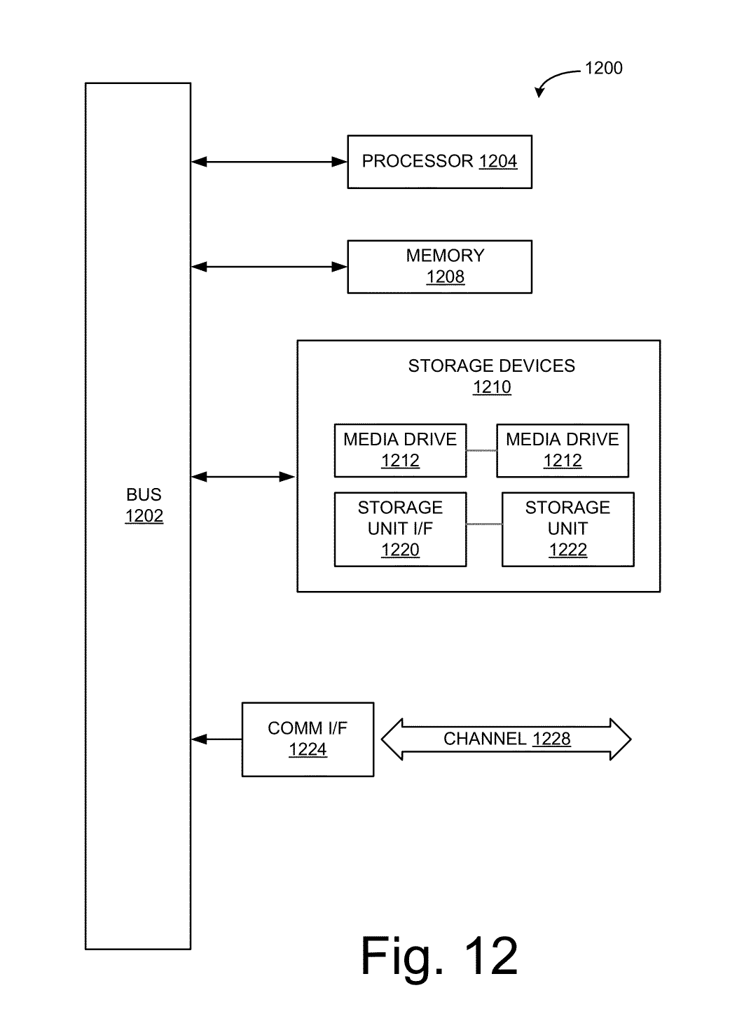

As used herein, the term module might describe a given unit of functionality that can be performed in accordance with one or more embodiments of the present invention. As used herein, a module might be implemented utilizing any form of hardware, software, or a combination thereof. For example, one or more processors, controllers, ASICs, PLAs, PALs, CPLDs, FPGAs, logical components, software routines or other mechanisms might be implemented to make up a module. In implementation, the various modules described herein might be implemented as discrete modules or the functions and features described can be shared in part or in total among one or more modules. In other words, as would be apparent to one of ordinary skill in the art after reading this description, the various features and functionality described herein may be implemented in any given application and can be implemented in one or more separate or shared modules in various combinations and permutations. Even though various features or elements of functionality may be individually described or claimed as separate modules, one of ordinary skill in the art will understand that these features and functionality can be shared among one or more common software and hardware elements, and such description shall not require or imply that separate hardware or software components are used to implement such features or functionality.

Where components or modules of the invention are implemented in whole or in part using software, in one embodiment, these software elements can be implemented to operate with a computing or processing module capable of carrying out the functionality described with respect thereto. One such example computing module is shown in FIG. 12. Various embodiments are described in terms of this example-computing module 1200. After reading this description, it will become apparent to a person skilled in the relevant art how to implement the invention using other computing modules or architectures.

Referring now to FIG. 12, computing module 1200 may represent, for example, computing or processing capabilities found within desktop, laptop and notebook computers; hand-held computing devices (PDA's, smart phones, cell phones, palmtops, etc.); mainframes, supercomputers, workstations or servers; or any other type of special-purpose or general-purpose computing devices as may be desirable or appropriate for a given application or environment. Computing module 1200 might also represent computing capabilities embedded within or otherwise available to a given device. For example, a computing module might be found in other electronic devices such as, for example, digital cameras, navigation systems, cellular telephones, portable computing devices, modems, routers, WAPs, terminals and other electronic devices that might include some form of processing capability.

Computing module 1200 might include, for example, one or more processors, controllers, control modules, or other processing devices, such as a processor 1204. Processor 1204 might be implemented using a general-purpose or special-purpose processing engine such as, for example, a microprocessor, controller, or other control logic. In the illustrated example, processor 1204 is connected to a bus 1202, although any communication medium can be used to facilitate interaction with other components of computing module 1200 or to communicate externally.

Computing module 1200 might also include one or more memory modules, simply referred to herein as main memory 1208. For example, preferably random access memory (RAM) or other dynamic memory, might be used for storing information and instructions to be executed by processor 1204. Main memory 1208 might also be used for storing temporary variables or other intermediate information during execution of instructions to be executed by processor 1204. Computing module 1200 might likewise include a read only memory (“ROM”) or other static storage device coupled to bus 1202 for storing static information and instructions for processor 1204.

The computing module 1200 might also include one or more various forms of information storage mechanism 1210, which might include, for example, a media drive 1212 and a storage unit interface 1220. The media drive 1212 might include a drive or other mechanism to support fixed or removable storage media 1214. For example, a hard disk drive, a floppy disk drive, a magnetic tape drive, an optical disk drive, a CD or DVD drive (R or RW), or other removable or fixed media drive might be provided. Accordingly, storage media 1214 might include, for example, a hard disk, a floppy disk, magnetic tape, cartridge, optical disk, a CD or DVD, or other fixed or removable medium that is read by, written to or accessed by media drive 1212. As these examples illustrate, the storage media 1214 can include a computer usable storage medium having stored therein computer software or data.

In alternative embodiments, information storage mechanism 1210 might include other similar instrumentalities for allowing computer programs or other instructions or data to be loaded into computing module 1200. Such instrumentalities might include, for example, a fixed or removable storage unit 1222 and an interface 1220. Examples of such storage units 1222 and interfaces 1220 can include a program cartridge and cartridge interface, a removable memory (for example, a flash memory or other removable memory module) and memory slot, a PCMCIA slot and card, and other fixed or removable storage units 1222 and interfaces 1220 that allow software and data to be transferred from the storage unit 1222 to computing module 1200.

Computing module 1200 might also include a communications interface 1224. Communications interface 1224 might be used to allow software and data to be transferred between computing module 1200 and external devices. Examples of communications interface 1224 might include a modem or softmodem, a network interface (such as an Ethernet, network interface card, WiMedia, IEEE 802.XX or other interface), a communications port (such as for example, a USB port, IR port, RS232 port Bluetooth® interface, or other port), or other communications interface. Software and data transferred via communications interface 1224 might typically be carried on signals, which can be electronic, electromagnetic (which includes optical) or other signals capable of being exchanged by a given communications interface 1224. These signals might be provided to communications interface 1224 via a channel 1228. This channel 1228 might carry signals and might be implemented using a wired or wireless communication medium. Some examples of a channel might include a phone line, a cellular link, an RF link, an optical link, a network interface, a local or wide area network, and other wired or wireless communications channels.

In this document, the terms “computer program medium” and “computer usable medium” are used to generally refer to media such as, for example, memory 1208, storage unit 1220, media 1214, and channel 1228. These and other various forms of computer program media or computer usable media may be involved in carrying one or more sequences of one or more instructions to a processing device for execution. Such instructions embodied on the medium, are generally referred to as “computer program code” or a “computer program product” (which may be grouped in the form of computer programs or other groupings). When executed, such instructions might enable the computing module 1200 to perform features or functions of the present invention as discussed herein.

While various embodiments of the present invention have been described above, it should be understood that they have been presented by way of example only, and not of limitation. Likewise, the various diagrams may depict an example architectural or other configuration for the invention, which is done to aid in understanding the features and functionality that can be included in the invention. The invention is not restricted to the illustrated example architectures or configurations, but the desired features can be implemented using a variety of alternative architectures and configurations. Indeed, it will be apparent to one of skill in the art how alternative functional, logical or physical partitioning and configurations can be implemented to implement the desired features of the present invention. Also, a multitude of different constituent module names other than those depicted herein can be applied to the various partitions. Additionally, with regard to flow diagrams, operational descriptions and method claims, the order in which the steps are presented herein shall not mandate that various embodiments be implemented to perform the recited functionality in the same order unless the context dictates otherwise.

Although the invention is described above in terms of various exemplary embodiments and implementations, it should be understood that the various features, aspects and functionality described in one or more of the individual embodiments are not limited in their applicability to the particular embodiment with which they are described, but instead can be applied, alone or in various combinations, to one or more of the other embodiments of the invention, whether or not such embodiments are described and whether or not such features are presented as being a part of a described embodiment. Thus, the breadth and scope of the present invention should not be limited by any of the above-described exemplary embodiments.

Terms and phrases used in this document, and variations thereof, unless otherwise expressly stated, should be construed as open ended as opposed to limiting. As examples of the foregoing: the term “including” should be read as meaning “including, without limitation” or the like; the term “example” is used to provide exemplary instances of the item in discussion, not an exhaustive or limiting list thereof; the terms “a” or “an” should be read as meaning “at least one,” “one or more” or the like; and adjectives such as “conventional,” “traditional,” “normal,” “standard,” “known” and terms of similar meaning should not be construed as limiting the item described to a given time period or to an item available as of a given time, but instead should be read to encompass conventional, traditional, normal, or standard technologies that may be available or known now or at any time in the future. Likewise, where this document refers to technologies that would be apparent or known to one of ordinary skill in the art, such technologies encompass those apparent or known to the skilled artisan now or at any time in the future.

The presence of broadening words and phrases such as “one or more,” “at least,” “but not limited to” or other like phrases in some instances shall not be read to mean that the narrower case is intended or required in instances where such broadening phrases may be absent. The use of the term “module” does not imply that the components or functionality described or claimed as part of the module are all configured in a common package. Indeed, any or all of the various components of a module, whether control logic or other components, can be combined in a single package or separately maintained and can further be distributed in multiple groupings or packages or across multiple locations.

Additionally, the various embodiments set forth herein are described in terms of exemplary block diagrams, flow charts and other illustrations. As will become apparent to one of ordinary skill in the art after reading this document, the illustrated embodiments and their various alternatives can be implemented without confinement to the illustrated examples. For example, block diagrams and their accompanying description should not be construed as mandating a particular architecture or configuration.

1. An electronics housing assembly, comprising:
an electronics housing comprising a housing wall;
the housing wall comprising a plurality of panels;
the panels each comprising a plurality of surfaces, the surfaces of a given panel forming a pseudo-fractal structure on that panel, thereby forming a plurality of pseudo-fractals structures; and
wherein the plurality of pseudo-fractal structures are configured such that the housing wall has a predetermined distribution of resonant frequencies greater than a predetermined threshold frequency.

2. The electronics housing assembly of claim 1, wherein a pseudo-fractal structure of the plurality of pseudo-fractal structures comprises a plurality of grooves etched into a panel of the plurality of panels; and wherein the grooves define the plurality of surfaces of the panel.

3. The electronics housing assembly of claim 1, wherein the housing comprises a laminate structure, and the pseudo-fractal structure is disposed in an intermediate laminate tier in the housing and surrounds a through hole for a mechanical connector.

4. The electronics housing assembly of claim 1, further comprising:
a second electronics housing comprising a second housing wall;
the second housing wall coupled to the first housing wall, and the second housing wall comprising a second plurality of panels;
the second plurality of panels each comprising a plurality of surfaces, the surfaces of a given panel of the second plurality of panels forming a conjugate pseudo-fractal structure with a corresponding pseudo-fractal structure of the first plurality.

5. The electronics housing assembly of claim 4, further comprising:
a system housing containing the first electronics housing and the second electronics housing; and
a plurality of dampeners coupling the first electronics housing and the second electronics housing to the system housing.

6. The electronics housing assembly of claim 1, wherein the resonant frequencies within the predetermined distribution of resonant frequencies greater than then predetermined threshold frequency are distributed in an interval between 0.8f_{c} to 1.2f_{c}, where f_{c} is the center frequency of the predetermined distribution of resonant frequencies.

7. The electronics housing assembly of claim 1, wherein the maximum amplitude of a resonant frequency of within the predetermined distribution of resonant frequencies is less than a predetermined threshold when the electronics housing assembly is exposed to a predetermined driving vibration.

8. A function centric data system, comprising:
a data acquisition unit, the data acquisition unit comprising:
a first bus coupled to an external bus interface;
a second bus coupled to an internal bus;
a first avionics system module coupled to the first bus and the second bus;
a second avionics system module coupled to the first bus and the second bus;
a bulk memory unit, coupled to the second bus and providing memory for operation of the first and second avionics;
and a plurality of processors coupled to the second bus and executing programs controlling the operation of the first avionics system module and the second avionics system module; and
a control panel communicatively coupled to the data acquisition unit;
a power line coupled to the control panel and the data acquisition unit and providing power to the control panel under control of the data acquisition unit;
a signal line coupled to the control panel and the data acquisition unit to enable the plurality of processors to control operation of the control panel.

9. The function centric data system of claim 8, wherein the first avionics system module comprises a data recorder controlled by the processors, the data recorder configured to sample data provided by external avionics systems at a predetermined sampling rate sufficient to capture a predetermined change in data over a predetermined time interval.

10. The function centric data system of claim 8, wherein the first avionics systems module or the second avionics system module comprises a signal data computer, an advanced signal data computer, a data bus recording module, a crash survivable memory unit, a removable memory module, a cockpit voice recorder, a cockpit video recorder, an analog sensor acquisition unit, an engine monitoring module, or a terrain awareness warning system.

11. The function centric data system of claim 8, wherein the first processor is a main system processor and the second processor is a back up system processor.

12. The function centric data system of claim 11, wherein the first processor is configure to process operations of at least one of the avionics system modules and the back up system processor is configure to process operations for at least one other of the avionics system modules if operation of the other avionics system modules exceeds the first processor's processing power.

13. The function centric data system of claim 8, further comprising a plurality of interfaces coupled to the first bus, the plurality of interfaces configured to interface with a corresponding plurality of external avionics systems.

14. The function centric data system of claim 8, wherein the data acquisition unit is configured to implement an operational flight program (OFP), comprising:
identifying a plurality of available OFP modules;
identifying a plurality of communications interfaces;
selecting a set of the plurality of available OFP modules according to the identified plurality of communications interfaces;
diagnosing the functionality of the communications interfaces using the selected set of the OFP modules;
receiving a status report of functional interfaces;
selecting a subset of the set of OFP modules for operation.

15. A method of network communication hand off, comprising
a first network device connecting to a second network device;
the first network device exchanging location information with the second network device;
the first network device exchanging signal strength information with the second network device;
the first network device exchanging antenna gain pattern information with the second network device;
the first network device connecting to a third network device;
the first network device exchanging location information with the third network device;
the first network device exchanging signal strength information with the third network device;
the first network device exchanging antenna gain pattern information with the third network device;
the first network device receiving a request from the second network device to hand off the aircraft communication system to the second network device, the request including location information from the aircraft communication system;
the first network device estimating a future signal strength and data throughput of a connection between the second network device and the aircraft communication system and a future signal strength and data throughput of a connection between the third network device and the aircraft communication system; and
based on the evaluation, granting or denying the hand off request to the second network device.

16. The method claim 15, wherein the request includes velocity vector information from the aircraft communication system.

17. The method of claim 16, further comprising the first network device computing the future location of the aircraft communication system using the velocity vector information to estimate the future signal strength and data throughput.

18. The method of claim 17, wherein the first network device and second network device comprise relay systems for relaying data from the aircraft communication system to a ground station.

19. The method of claim 18, wherein the data comprises data stored in a bulk memory module in a function centric data system.

20. A non-transitory computer readable medium comprising program code configured to cause a first network device to perform a method of communication hand off, comprising
the first network device connecting to a second network device;
the first network device exchanging location information with the second network device;
the first network device exchanging signal strength information with the second network device;
the first network device exchanging antenna gain pattern information with the second network device;
the first network device connecting to a third network device;
the first network device exchanging location information with the third network device;
the first network device exchanging signal strength information with the third network device;
the first network device exchanging antenna gain pattern information with the third network device;
the first network device receiving a request from the second network device to hand off the aircraft communication system to the second network device, the request including location information from the aircraft communication system;
the first network device estimating a future signal strength and data throughput of a connection between the second network device and the aircraft communication system and a future signal strength and data throughput of a connection between the third network device and the aircraft communication system; and
based on the evaluation, granting or denying the hand off request to the second network device.

21. The computer readable medium of claim 20, wherein the request includes velocity vector information from the aircraft communication system.

22. The computer readable medium of claim 21, the method further comprising the first network device computing the future location of the aircraft communication system using the velocity vector information to estimate the future signal strength and data throughput.

23. The computer readable medium of claim 22, wherein the first network device and second network device comprise relay systems for relaying data from the aircraft communication system to a ground station.

24. The computer readable medium of claim 23, wherein the data comprises data stored in a bulk memory module in a function centric data system.

25. A method of network communications, comprising:
a first network device receiving location information of a plurality of proximate network devices;
the first network device broadcasting the first network device's location information to the plurality of proximate network device;
the first network device receiving location information and directionality information regarding a base station antenna;
the first network device using the received location information of the plurality of proximate network devices, the location information of the base station antenna, and the directionality information to determine a multi-hop network route between the proximate network devices and the base stations.

26. The method of claim 25, further comprising the first network device maintaining a routing table of routes to the base station antenna via the proximate network devices.

27. The method of claim 26, wherein the routing table includes the location information of the plurality of proximate network devices and the directionality information of the base station antenna.

28. The method of claim 25, further comprising the first network device receiving directionality information of the plurality of proximate network devices.

29. A non-transitory computer readable medium comprising program code configured to cause a first network device to perform a method of network communications, comprising:
the first network device receiving location information of a plurality of proximate network devices;
the first network device broadcasting the first network device's location information to the plurality of proximate network device;
the first network device receiving location information and directionality information regarding a base station antenna;
the first network device using the received location information of the plurality of proximate network devices, the location information of the base station antenna, and the directionality information to determine a multi-hop network route between the proximate network devices and the base stations.

30. The computer readable medium of claim 29, the method further comprising the first network device maintaining a routing table of routes to the base station antenna via the proximate network devices.

31. The computer readable medium of claim 30, wherein the routing table includes the location information of the plurality of proximate network devices and the directionality information of the base station antenna.

32. The computer readable medium of claim 29, the method further comprising the first network device receiving directionality information of the plurality of proximate network devices.

33. A method of video processing, comprising:
receiving a video at a predetermined frame rate, the video including images of an articulated object;
identifying a kinematic analog parameterized object from the images of the articulated object;
classifying the kinematic analog parameterized object according whether the kinematic analog parameterized has translational, rotational, gradual, or discrete characteristics;
digitizing the images of the articulated object according to the classification.

34. The method of video processing of claim 33, wherein the articulated object is an avionics instrument display.

35. The method of video processing of claim 33, wherein the articulate object is an aircraft control surface.

36. The method of video processing of claim 33, wherein the video is received from a cockpit video recorder.

37. The method of video processing of claim 33, wherein the articulated object has a predetermined orientation in the images.

38. The method of video processing of claim 33, further comprising:
obtaining a first set of data regarding the articulated object from the digitized images;
obtaining a second set of data regarding the articulated object from a sensor measuring the articulated object or a data source controlling the articulated object;
comparing the first set of data with the second set of data to identify discrepancies.

39. A non-transitory computer readable medium comprising program code configured to cause an electronics device to perform a method of video processing, comprising:
receiving a video at a predetermined frame rate, the video including images of an articulated object;
identifying a kinematic analog parameterized object from the images of the articulated object;
classifying the kinematic analog parameterized object according whether the kinematic analog parameterized has translational, rotational, gradual, or discrete characteristics;
digitizing the images of the articulated object according to the classification.

40. The computer readable medium of claim 39, wherein the articulated object is an avionics instrument display.

41. The computer readable medium of claim 39, wherein the articulate object is an aircraft control surface.

42. The computer readable medium of claim 39, wherein the video is received from a cockpit video recorder.

43. The computer readable medium of claim 39, wherein the articulated object has a predetermined orientation in the images.

44. The computer readable medium of claim 39, the method further comprising:
obtaining a first set of data regarding the articulated object from the digitized images;
obtaining a second set of data regarding the articulated object from a sensor measuring the articulated object or a data source controlling the articulated object;
comparing the first set of data with the second set of data to identify discrepancies.

45. A method of data analysis for predicting a possible future avionics failure, comprising:
identifying a set of possible failures;
identifying a corresponding set of data measurements;
identifying a set of probabilities of measuring particular data measurements given the occurrence of the possible failures;
forming a matrix of probabilities of the possible failures given the data measurements;
normalizing the matrix;
measuring data during avionics operation; and
applying the normalized matrix to the measured data to predict the possible future avionics failure.

46. The method of claim 45, further comprising:
obtaining a matrix of probabilities of data measurement given possible failures; and
obtaining a set of absolute probabilities of possible failures;
wherein the step of forming the matrix of probabilities of the possible failures given the data measurement comprises computing the matrix of probabilities of the possible failures from the matrix of probabilities of data measurement given possible failures and the set of absolute probabilities of possible failures.

47. The method of claim 45, further comprising identifying a set of data measurements that enable the matrix of probabilities of the possible failures given the data measurements to be diagonal.

48. The method of claim 45, wherein the corresponding set of data measurements is a set of measurements of operational variables, with an operational variable for each possible failure.

49. The method of claim 48, wherein each operational variable is primarily predictive of a single possible failure.

50. The method of claim 49, wherein the matrix comprises diagonal elements, each diagonal element corresponding to the probability of a possible failure given a measurement of the diagonal element's corresponding primarily predictive operational variable.

51. The method of claim 50, wherein the matrix further comprises off-diagonal element, each off-diagonal element corresponding to the probability of a possible failure given a measurement of an operational variable other than the possible failure's corresponding primarily predictive operational variable.

52. A non-transitory computer readable medium comprising program code configured to cause an electronics device to perform a method of data analysis for predicting a possible future avionics failure, comprising:
identifying a set of possible failures;
identifying a corresponding set of data measurements;
identifying a set of probabilities of measuring particular data measurements given the occurrence of the possible failures;
forming a matrix of probabilities of the possible failures given the data measurements;
normalizing the matrix;
measuring data during avionics operation; and
applying the normalized matrix to the measured data to predict the possible future avionics failure.

53. The computer readable medium of claim 52, the method further comprising:
obtaining a matrix of probabilities of data measurement given possible failures; and
obtaining a set of absolute probabilities of possible failures;
wherein the step of forming the matrix of probabilities of the possible failures given the data measurement comprises computing the matrix of probabilities of the possible failures from the matrix of probabilities of data measurement given possible failures and the set of absolute probabilities of possible failures.

54. The computer readable medium of claim 52, the method further comprising identifying a set of data measurements that enable the matrix of probabilities of the possible failures given the data measurements to be diagonal.

55. The computer readable medium of claim 52, wherein the corresponding set of data measurements is a set of measurements of operational variables, with an operational variable for each possible failure.

56. The computer readable medium of claim 55, wherein each operational variable is primarily predictive of a single possible failure.

57. The computer readable medium of claim 56, wherein the matrix comprises diagonal elements, each diagonal element corresponding to the probability of a possible failure given a measurement of the diagonal element's corresponding primarily predictive operational variable.

58. The computer readable medium of claim 57, wherein the matrix further comprises off-diagonal element, each off-diagonal element corresponding to the probability of a possible failure given a measurement of an operational variable other than the possible failure's corresponding primarily predictive operational variable.

59. A method of identifying data events predictive of failures, comprising:
obtaining a first data set, the data set including measurements of failure points of a type of avionics structure;
from the first data set, identifying a plurality of control variables and a state variable, the state variable being discontinuous at the failure points, and the control variables having a continuous path at the failure points;
identifying a catastrophe potential function depending on the control variables and the state variable;
identifying a bifurcation set from the catastrophe potential function;
storing the bifurcation set of the catastrophe potential on a non-transitory computer readable medium.

60. The method of claim 59, further comprising:
receiving operational data regarding an avionics structure of the type of avionics structure;
obtaining a control trajectory of the avionics structure using the operational data and the bifurcation set, the control trajectory reflecting a catastrophic tangential point;
evaluating the operational data to determine if the avionics structure operated within a threshold distance of the catastrophic tangential point.

61. The method of claim 59, wherein the data set is obtained from an equation of state for the avionics structure, the equation of state depending on the at least one control variable and the at least one state variable.

62. The method of claim 61, wherein the measurements of the failure points are obtained from differentiating the equation of state with respect to the state variable.

63. The method of claim 59, wherein the state variable is one of a plurality of state variables, each state variable being discontinuous at the failure points.

64. The method of claim 59, wherein the bifurcation set comprises a plurality of cusps, the cusps reflecting the failure points.

65. A non-transitory computer readable medium comprising program code configured to cause an electronics device to perform a method of identifying data events predictive of failures, comprising:
obtaining a first data set, the data set including measurements of failure points of a type of avionics structure;
from the first data set, identifying a plurality of control variables and a state variable, the state variable being discontinuous at the failure points, and the control variables having a continuous path at the failure points;
identifying a catastrophe potential function depending on the control variables and the state variable;
identifying a bifurcation set from the catastrophe potential function;
storing the bifurcation set of the catastrophe potential on a non-transitory computer readable medium.

66. The computer readable medium of claim 65, further comprising:
receiving operational data regarding an avionics structure of the type of avionics structure;
obtaining a control trajectory of the avionics structure using the operational data and the bifurcation set, the control trajectory reflecting a catastrophic tangential point;
evaluating the operational data to determine if the avionics structure operated within a threshold distance of the catastrophic tangential point.

67. The computer readable medium of claim 65, wherein the data set is obtained from an equation of state for the avionics structure, the equation of state depending on the at least one control variable and the at least one state variable.

68. The computer readable medium of claim 6761, wherein the measurements of the failure points are obtained from differentiating the equation of state with respect to the state variable.

69. The computer readable medium of claim 65, wherein the state variable is one of a plurality of state variables, each state variable being discontinuous at the failure points.

70. The computer readable medium of claim 65, wherein the bifurcation set comprises a plurality of cusps, the cusps reflecting the failure points.
